(19) United States
(12) Patent Application Publication
(10) Pub. No.: US 2024/0284672 A1
(43) Pub. Date: Aug. 22, 2024

(54) MERGED CAVITIES FOR CONDUCTOR FORMATION IN A MEMORY DIE

(71) Applicant: Micron Technology, Inc., Boise, ID (US)

(72) Inventors: David H. Wells, Boise, ID (US); Matthew J. King, Boise, ID (US); Indra V. Chary, Boise, ID (US); Yoshiaki Fukuzumi, Yokohama (JP); Lifang Xu, Boise, ID (US); Paolo Tessariol, Arcore (MB) (IT); Shuangqiang Luo, Boise, ID (US)

(21) Appl. No.: 18/443,013

(22) Filed: Feb. 15, 2024

Related U.S. Application Data
(60) Provisional application No. 63/486,175, filed on Feb. 21, 2023.

(51) Int. Cl. H10B 43/27; H10B 43/10

(52) U.S. Cl. CPC H10B 43/27; H10B 43/10

(57) ABSTRACT

Methods, systems, and devices for merged cavities for conductor formation in a memory die are described. An array of cavities may be formed through a stack of material layers of a memory die, and conductors may be formed at least in part by merging some of the cavities of the array. Such cavities may be sized in accordance with a relatively smallest feature that implements a subset of such cavities, and a smallest associated feature may be formed using a first subset of the array of cavities. Conductors may be formed at least in part by merging two or more cavities of a second subset of the array of cavities using a material removal operation to remove portions of the stack of material layers. Such merging may support conductors being formed with a cross-section that is greater than a cross-section of other features formed using such cavities that are not merged.

### CROSS REFERENCE

The present application for patent claims the benefit of U.S. Provisional Patent Application No. 63/486,175 by WELLS et al., entitled “MERGED CAVITIES FOR CONDUCTOR FORMATION IN A MEMORY DIE,” filed Feb. 21, 2023, assigned to the assignee hereof, and expressly incorporated by reference in its entirety herein.

### TECHNICAL FIELD

The following relates to one or more systems for memory, including merged cavities for conductor formation in a memory die.

### BACKGROUND

Memory devices are widely used to store information in various electronic devices such as computers, user devices, wireless communication devices, cameras, digital displays, and the like. Information is stored by programming memory cells within a memory device to various states. For example, binary memory cells may be programmed to one of two supported states, often corresponding to a logic 1 or a logic 0. In some examples, a single memory cell may support more than two possible states, any one of which may be stored by the memory cell. To access information stored by a memory device, a component may read (e.g., sense, detect, retrieve, identify, determine, evaluate) the state of one or more memory cells within the memory device. To store information, a component may write (e.g., program, set, assign) one or more memory cells within the memory device to corresponding states.

Various types of memory devices exist, including magnetic hard disks, random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), 3-dimensional cross-point memory (3D cross point), not-or (NOR) and not-and (NAND) memory devices, and others. Memory devices may be described in terms of volatile configurations or non-volatile configurations. Volatile memory cells (e.g., DRAM) may lose their programmed states over time unless they are periodically refreshed by an external power source. Non-volatile memory cells (e.g., NAND) may maintain their programmed states for extended periods of time even in the absence of an external power source.

### BRIEF DESCRIPTION OF THE DRAWINGS

FIG. 1 illustrates an example of a system that supports merged cavities for conductor formation in a memory die in accordance with examples as disclosed herein.

FIG. 2 illustrates an example of a memory architecture that supports merged cavities for conductor formation in a memory die in accordance with examples as disclosed herein.

FIG. 3 through 13 illustrate examples of fabrication operations that may support merged cavities for conductor formation in a memory die in accordance with examples as disclosed herein

FIG. 14 illustrates a flowchart showing a method or methods that support merged cavities for conductor formation in a memory die in accordance with examples as disclosed herein.

### DETAILED DESCRIPTION

In some memory manufacturing operations, one or more materials may be deposited over a substrate, such as a semiconductor substrate, and portions of the one or more materials may be removed in accordance with various patterning operations. For example, a pattern of cavities may be formed by removing one or more materials along a thickness direction in accordance with a pattern of openings having one or more various cross-sectional profiles. In some examples, memory cells may be formed at least in part by depositing one or more storage materials in some cavities, and conductors (e.g., to support access of the memory cells or for other operations or signaling) may be formed at least in part by depositing one or more conductive materials in some other cavities.

In some implementations, conductors may be associated with configured conductivity or resistance values, and cavities for conductor formation may have different sizes or patterns to support the conductivity or resistance values. Forming cavities having different sizes or patterns, however, may be associated with non-uniformities (e.g., structural non-uniformities, processing non-uniformities) within a memory array region or in transitions between regions of the memory array that use differently sized cavities. Additionally, or alternatively, forming patterns of cavities having different sizes (e.g., high aspect ratio cavities) may be associated with relatively complex or expensive processing. Thus, in some examples, it may be desirable to form an array of cavities of a uniform size, and form memory cells and conductors from respective subsets of the same array of cavities. However, the cavities may be formed in accordance with a relatively small cross-section (e.g., associated with formation of a smallest feature, such as memory pillar formation), and a desired conductivity or resistance value may not be supported by a conductor formed in a cavity of the relatively small cross-section.

In accordance with examples as disclosed herein, an array of cavities may be formed through a stack of material layers of a memory die, and conductors (e.g., conductive pillars) may be formed at least in part by merging some of the cavities of the array. For example, such cavities may be sized in accordance with a relatively smallest feature that implements a subset of such cavities (e.g., memory pillar formation), and the smallest associated feature (e.g., the memory pillars) may be formed using a first subset of the array of cavities. Conductors may be formed at least in part by merging two or more cavities of a second subset of the array of cavities. For example, patterns of cavities may be merged using a selective material removal (e.g., to form voids that extend between two or more adjacent cavities, such as one or more nearest neighbor cavities, or to remove all materials between adjacent cavities), and a conductive material may be formed in the merged cavities to form conductive pillars. Such merging may support conductors being formed with a cross-section that is greater than a single cavity. Accordingly, a uniform pattern of cavities can be formed to maintain processing and structural consistency across the memory die, and some cavities can be merged to provide larger openings for conductors to achieve a desired conductivity or resistivity value. Additionally, forming memory pillars and conductive pillars from the same array of cavities may result in improved processing efficiency and lowered production costs.

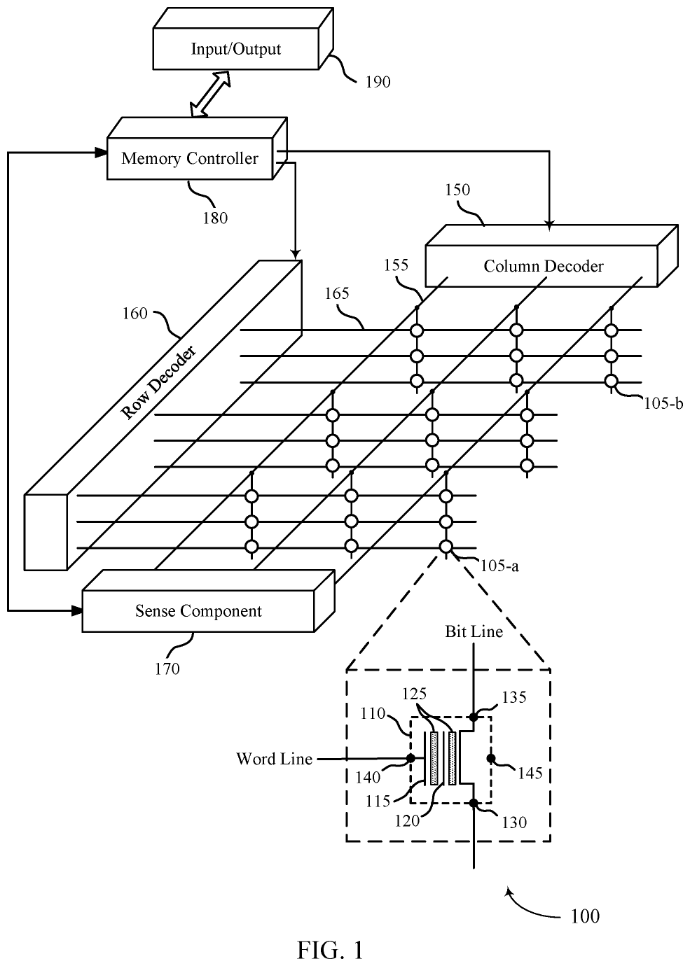

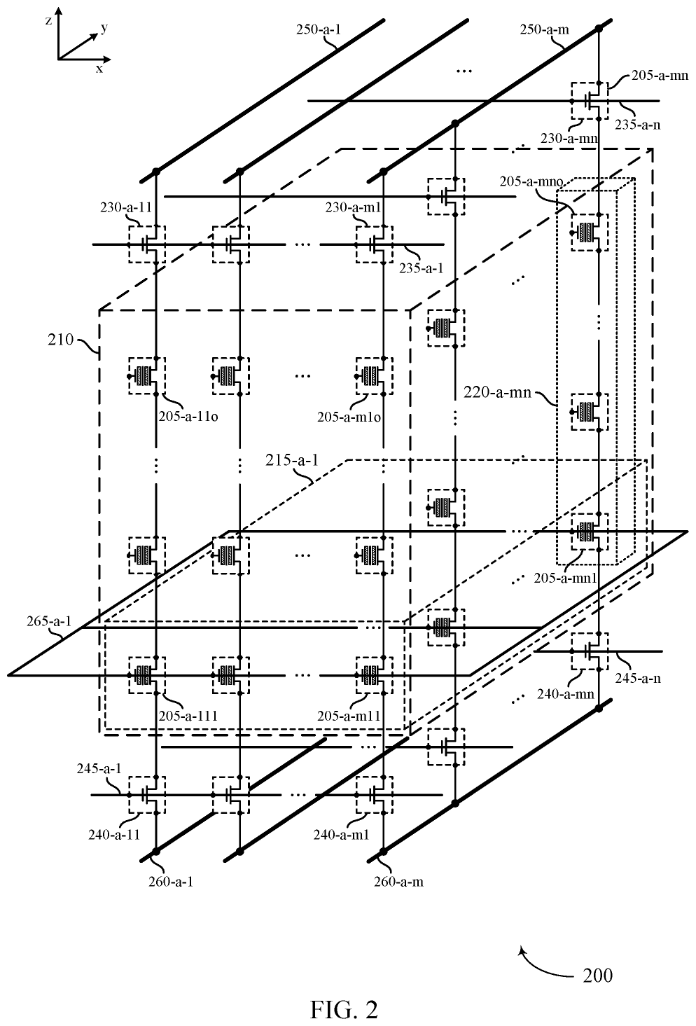

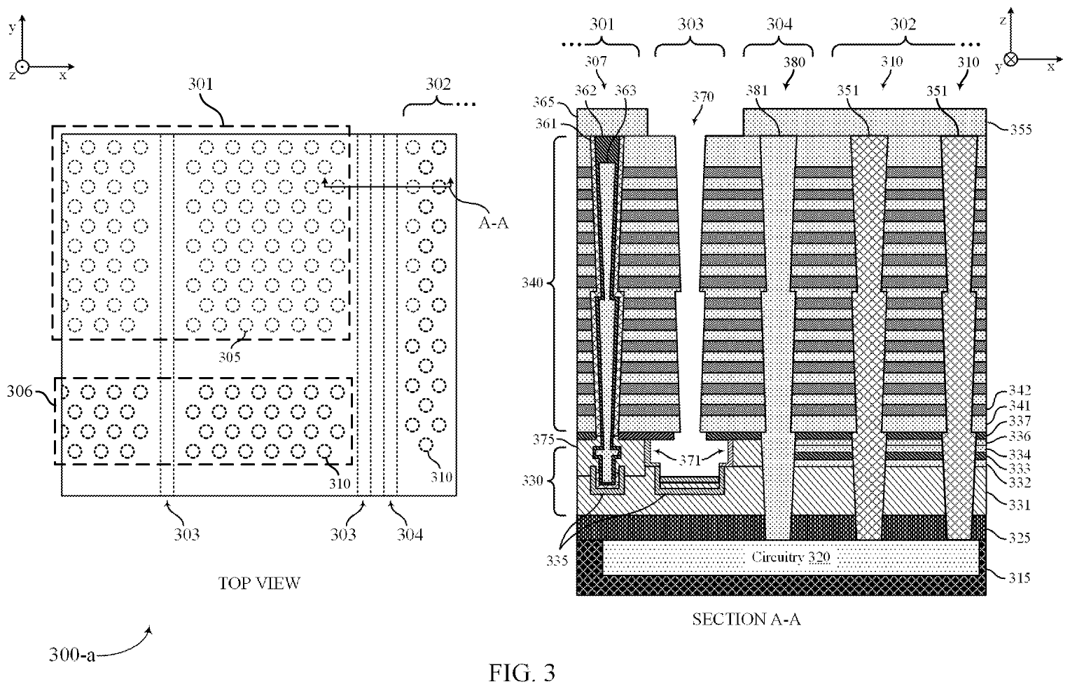

Features of the disclosure are described and illustrated in the context of systems, devices, and circuits with reference to FIGS. 1 and 2. Features of the disclosure are described and illustrated in the context of material arrangements and methods with reference to FIGS. 3 through 14.

FIG. 1 illustrates an example of a memory device 100 that supports merged cavities for conductor formation in a memory die in accordance with examples as disclosed herein. FIG. 1 is an illustrative representation of various components and features of the memory device 100. As such, the components and features of the memory device 100 are shown to illustrate functional interrelationships, and not necessarily physical positions within the memory device 100. Further, although some elements included in FIG. 1 are labeled with a numeric indicator, some other corresponding elements are not labeled, even though they are the same or would be understood to be similar, to increase visibility and clarity of the depicted features.

The memory device 100 may include one or more memory cells 105, such as memory cell 105-a and memory cell 105-b. In some examples, a memory cell 105 may be a NAND memory cell, such as in the blow-up diagram of memory cell 105-a. Each memory cell 105 may be programmed to store a logic value representing one or more bits of information. In some examples, a single memory cell 105—such as a memory cell 105 configured as a single-level cell (SLC)—may be programmed to one of two supported states and thus may store one bit of information at a time (e.g., a logic 0 or a logic 1). In some other examples, a single memory cell 105—such a memory cell 105 configured as a multi-level cell (MLC), a tri-level cell (TLC), a quad-level cell (QLC), or other type of multiple-level memory cell 105—may be programmed to one state of more than two supported states and thus may store more than one bit of information at a time.

In some NAND memory arrays, each memory cell 105 may be illustrated as a transistor that includes a charge trapping structure (e.g., a floating gate, a replacement gate, a dielectric material) for storing an amount of charge representative of a logic value. For example, the blow-up in FIG. 1 illustrates a NAND memory cell 105-a that includes a transistor 110 (e.g., a metal-oxide-semiconductor (MOS) transistor) that may be used to store a logic value. The transistor 110 may include a control gate 115 and a charge trapping structure 120 (e.g., a floating gate, a replacement gate), where the charge trapping structure 120 may, in some examples, be between two portions of dielectric material 125. The transistor 110 also may include a first node 130 (e.g., a source or drain) and a second node 135 (e.g., a drain or source). A logic value may be stored in transistor 110 by storing (e.g., writing) a quantity of electrons (e.g., an amount of charge) on the charge trapping structure 120. An amount of charge to be stored on the charge trapping structure 120 may depend on the logic value to be stored. The charge stored on the charge trapping structure 120 may affect the threshold voltage of the transistor 110, thereby affecting the amount of current that flows through the transistor 110 when the transistor 110 is activated (e.g., when a voltage is applied to the control gate 115, when the memory cell 105-a is read). In some examples, the charge trapping structure 120 may be an example of a floating gate or a replacement gate structure. For example, a NAND array may include multiple control gates 115 and charge trapping structures 120 arranged around a single channel (e.g., a horizontal channel, a vertical channel, a columnar channel, a pillar channel).

A logic value stored in the transistor 110 may be sensed (e.g., as part of a read operation) by applying a voltage to the control gate 115 (e.g., to control node 140, via a word line 165) to activate the transistor 110 and measuring (e.g., detecting, sensing) an amount of current that flows through the first node 130 or the second node 135 (e.g., via a bit line 155). For example, a sense component 170 may determine whether an SLC memory cell 105 stores a logic 0 or a logic 1 in a binary manner (e.g., based on a presence or absence of a current through the memory cell 105 when a read voltage is applied to the control gate 115, based on whether the current is above or below a threshold current). For a multiple-level memory cell 105, a sense component 170 may determine a logic value stored in the memory cell 105 based on various intermediate threshold levels of current when a read voltage is applied to the control gate 115, or by applying different read voltages to the control gate and evaluating different resulting levels of current through the transistor 110, or various combinations thereof.

An SLC memory cell 105 may be written by applying one of two voltages (e.g., a voltage above a threshold or a voltage below a threshold) to memory cell 105 to store, or not store, an electric charge on the charge trapping structure 120 and thereby cause the memory cell 105 store one of two possible logic values. For example, when a first voltage is applied to the control node 140 (e.g., via a word line 165) relative to a bulk node 145 (e.g., a body node) for the transistor 110 (e.g., when the control node 140 is at a higher voltage than the bulk), electrons may tunnel into the charge trapping structure 120. Injection of electrons into the charge trapping structure 120 may be referred to as programming the memory cell 105 and may occur as part of a write operation. A programmed memory cell may, in some cases, be considered as storing a logic 0. When a second voltage is applied to the control node 140 (e.g., via the word line 165) relative to the bulk node 145 for the transistor 110 (e.g., when the control node 140 is at a lower voltage than the bulk node 145), electrons may leave the charge trapping structure 120. Removal of electrons from the charge trapping structure 120 may be referred to as erasing the memory cell 105 and may occur as part of an erase operation. An erased memory cell may, in some cases, be considered as storing a logic 1. In some cases, memory cells 105 may be programmed at a page level of granularity due to memory cells 105 of a page sharing a common word line 165, and memory cells 105 may be erased at a block level of granularity due to memory cells 105 of a block sharing commonly biased bulk nodes 145.

In some examples, writing a multiple-level (e.g., MLC, TLC, or QLC) memory cell 105 may involve applying different voltages to the memory cell 105 (e.g., to the control node 140 or bulk node 145 thereof) at a finer level of granularity to more finely control the amount of charge stored on the charge trapping structure 120, thereby enabling a larger set of logic values to be represented. Thus, multiple-level memory cells 105 may provide greater density of storage relative to SLC memory cells 105 but may, in some cases, involve narrower read or write margins or greater complexities for supporting circuitry.

A charge-trapping NAND memory cell 105 may operate similarly to a floating-gate NAND memory cell 105 but, instead of or in addition to storing a charge on a charge trapping structure 120, a charge-trapping NAND memory cell 105 may store a charge representing a logic state in a dielectric material between the control gate 115 and a channel (e.g., a channel between a first node 130 and a second node 135). Thus, a charge-trapping NAND memory cell 105 may include a charge trapping structure 120, or may implement charge trapping functionality in one or more portions of dielectric material 125, among other configurations.

In some examples, each page of memory cells 105 may be connected to a corresponding word line 165, and each column of memory cells 105 may be connected to a corresponding bit line 155 (e.g., digit line). Thus, one memory cell 105 may be located at the intersection of a word line 165 and a bit line 155. This intersection may be referred to as an address of a memory cell 105. In some cases, word lines 165 and bit lines 155 may be substantially perpendicular to one another, and may be generically referred to as access lines or select lines. In some examples, the access lines (e.g., the word lines 165 and the bit lines 155) may be formed in a direction away from a substrate of the memory device 100, and may each be positioned between layers of a dielectric material in an array region of the memory device 100. The direction away from the substrate may refer to a thickness (e.g., height) direction, and may be subject to some degree of skew associated with a manufacturing process.

Accessing memory cells 105 may be controlled through a row decoder 160 and a column decoder 150. For example, the row decoder 160 may receive a row address from the memory controller 180 and activate an appropriate word line 165 based on the received row address. Similarly, the column decoder 150 may receive a column address from the memory controller 180 and activate an appropriate bit line 155. Thus, by activating one word line 165 and one bit line 155, one memory cell 105 may be accessed. As part of such accessing, a memory cell 105 may be read (e.g., sensed) by sense component 170. For example, the sense component 170 may be configured to determine the stored logic value of a memory cell 105 based on a signal generated by accessing the memory cell 105. The signal may include a current, a voltage, or both a current and a voltage on the bit line 155 for the memory cell 105 and may depend on the logic value stored by the memory cell 105. The sense component 170 may include various circuitry (e.g., transistors, amplifiers) configured to detect and amplify a signal (e.g., a current or voltage) on a bit line 155. The logic value of memory cell 105 as detected by the sense component 170 may be output via input/output component 190. In some cases, a sense component 170 may be a part of a column decoder 150 or a row decoder 160, or a sense component 170 may otherwise be connected to or in electronic communication with a column decoder 150 or a row decoder 160.

A memory cell 105 may be programmed or written by activating the relevant word line 165 and bit line 155 to enable a logic value (e.g., representing one or more bits of information) to be stored in the memory cell 105. A column decoder 150 or a row decoder 160 may accept data (e.g., from the input/output component 190) to be written to the memory cells 105. In the case of NAND memory, a memory cell 105 may be written by storing electrons in a charge trapping structure or an insulating layer.

A memory controller 180 may control the operation (e.g., read, write, re-write, refresh) of memory cells 105 through the various components (e.g., row decoder 160, column decoder 150, sense component 170). In some cases, one or more of a row decoder 160, a column decoder 150, and a sense component 170 may be co-located with a memory controller 180. A memory controller 180 may generate row and column address signals in order to activate a desired word line 165 and bit line 155. In some examples, a memory controller 180 may generate and control various voltages or currents used during the operation of memory device 100.

In some techniques for manufacturing a memory device 100 (e.g., for manufacturing a memory die that includes one or more aspects of the memory device 100), one or more materials may be deposited over a substrate, such as a semiconductor substrate, and portions of the one or more materials may be removed in accordance with various patterning operations. In accordance with examples as disclosed herein, an array of cavities may be formed through a stack of material layers of a memory die to support aspects of a memory device 100, and conductors (e.g., conductive pillars, conductors associated with word lines 165 or bit lines 155) may be formed at least in part by merging some of the cavities of the array. For example, such cavities may be sized in accordance with a relatively smallest feature that implements a subset of such cavities (e.g., for formation of pillars of memory cells 105), and the smallest associated feature may be formed using a first subset of the array of cavities. Conductors may be formed at least in part by merging two or more cavities of a second subset of the array of cavities. For example, patterns of cavities may be merged using a selective material removal (e.g., to form voids that extend between two or more adjacent cavities, or to remove all materials between cavities), and a conductive material may be formed in the merged cavities to form conductive pillars. Such merging may support conductors being formed with a cross-section that is greater than a cross-section of a single cavity. Accordingly, a uniform pattern of cavities can be formed to maintain processing and structural consistency across the memory die, and some cavities can be merged to provide larger openings for conductors to achieve configured conductivity or resistivity values. Additionally, forming memory pillars and conductive pillars from the same array of cavities may result in improved processing efficiency and lowered production costs.

FIG. 2 illustrates an example of a memory architecture 200 that supports merged cavities for conductor formation in a memory die in accordance with examples as disclosed herein. The memory architecture 200 may be an example of a portion of a memory device, such as a memory device 100. Although some elements of a set of elements (e.g., an array of elements) are included in FIG. 2, some elements may be omitted for the sake of visibility and clarity of the depicted elements. Moreover, although some elements included in FIG. 2 are labeled with reference numbers, some other corresponding elements are not labeled, though they are the same or would be understood by a person having ordinary skill in the art to be similar. Aspects of the memory architecture 200 may be described with reference to an x-direction, a y-direction, and a z-direction of the illustrated coordinate system.

The memory architecture 200 includes a three-dimensional array of memory cells 205, which may be examples of memory cells 105 described with reference to FIG. 1 (e.g., transistors 110, NAND memory cells). For example, the memory cells 205 may be included in a block 210, which may be arranged as a 3D array of m memory cells along the x-direction, n memory cells along the y-direction, and o memory cells along the z-direction. Each memory cell 205 may be located (e.g., addressed) in accordance with an index i along the x-direction, an index j along the y-direction, and an index k along the z-direction (e.g., for locating a memory cell 205-a-ijk). A memory device 100 may include any quantity of one or more blocks 210 in accordance with examples as disclosed herein, and different blocks 210 may be adjacent along the x-direction, along the y-direction, or along the z-direction, or any combination thereof.

In the example of memory architecture 200, the block 210 may be divided into a set of pages 215 (e.g., a quantity of o pages 215) along the z-direction, including a page 215-a-1 associated with memory cells 205-a-111 through 205-a-mn1. In some examples, each page 215 may be associated with a same word line 265, (e.g., a word line 165 described with reference to FIG. 1), which may be coupled with a control gate 115 of each of the memory cells 205 of the page 215. For example, page 215-a-1 may be associated with a word line 265-a-1, and other pages 215-a-i may be associated with a different respective word line 265-a-i (not shown). In some examples, a word line 265 in accordance with the memory architecture 200 may be implemented as planar conductor (e.g., in an xy-plane) that is coupled with each of the memory cells 205 of the page 215.

In the example of memory architecture 200, the block 210 also may be divided into a set of strings 220 (e.g., a quantity of (m×n) strings 220) in an xy-plane, including a string 220-a-mn associated with memory cells 205-a-mn1 through 205-a-mno. In some examples, each string 220 may include a set of memory cells 205 connected in series (e.g., along the z-direction, in which a drain of one memory cell 205 in the string 220 may be coupled with a source of another memory cell 205 in the string 220). In some examples, memory cells 205 of a string 220 may be implemented along a common channel, such as a pillar channel (e.g., a columnar channel, a pillar of doped semiconductor) along the z-direction. Each memory cell 205 in a string 220 may be associated with a different word line 265, such that a quantity of word lines 265 in the memory architecture 200 may be equal to the quantity of memory cells 205 in a string 220. Accordingly, a string 220 may include memory cells 205 from multiple pages 215, and a page 215 may include memory cells 205 from multiple strings 220.

In some examples, memory cells 205 may be programmed (e.g., set to a logic 0 value) and read from in accordance with a granularity, such as at the granularity of the page 215, but may not be erasable (e.g., reset to a logic 1 value) in accordance with the granularity, such as the granularity of the page 215. For example, NAND memory may instead be erasable in accordance with a different (e.g., higher) level of granularity, such as at the level of granularity the block 210. In some cases, a memory cell 205 may be erased before it may be re-programmed. Different memory devices may have different read, write, or erase characteristics.

In some examples, each string 220 of a block 210 may be coupled with a respective transistor 230 (e.g., a string select transistor, a drain select transistor) at one end of the string 220 (e.g., along the z-direction) and a respective transistor 240 (e.g., a source select transistor, a ground select transistor) at the other end of the string 220. In some examples, a drain of each transistor 230 may be coupled with a bit line 250 of a set of bit lines 250 associated with the block 210, where the bit lines 250 may be examples of bit lines 155 described with reference to FIG. 1. A gate of each transistor 230 may be coupled with a select line 235 (e.g., a string select line, a drain select line). Thus, a transistor 230 may be used to couple a string 220 with a bit line 250 based on applying a voltage to the select line 235, and thus to the gate of the transistor 230. Although illustrated as separate lines along the x-direction, in some examples, select lines 235 may be common to all the transistors 230 associated with the block 210 (e.g., a commonly biased string select node). For example, like the word lines 265 of the block 210, select lines 235 associated with the block 210 may, in some examples, be implemented as a planar conductor (e.g., in an xy-plane) that is coupled with each of the transistors 230 associated with the block 210. In some examples, access lines (e.g., bit lines 250 and word lines 265) may be formed in a direction away from a substrate of the memory device 100, and may each be positioned between layers of a dielectric material in an array region of the memory device 100. The direction away from the substrate may refer to the z-direction (e.g., a thickness or height direction), and may be subject to some degree of skew associated with a manufacturing process.

In some examples, a source of each transistor 240 associated with the block 210 may be coupled with a source line 260 of a set of source lines 260 associated with the block 210. In some examples, the set of source lines 260 may be associated with a common source node (e.g., a ground node) corresponding to the block 210. A gate of each transistor 240 may be coupled with a select line 245 (e.g., a source select line, a ground select line). Thus, a transistor 240 may be used to couple a string 220 with a source line 260 based on applying a voltage to the select line 245, and thus to the gate of the transistor 240. Although illustrated as separate lines along the x-direction, in some examples, select lines 245 also may be common to all the transistors 240 associated with the block 210 (e.g., a commonly biased ground select node). For example, like the word lines 265 of the block 210, select lines 245 associated with the block 210 may, in some examples, be implemented as a planar conductor (e.g., in an xy-plane) that is coupled with each of the transistors 240 associated with the block 210.

To operate the memory architecture 200 (e.g., to perform a program operation, a read operation, or an erase operation on one or more memory cells 205 of the block 210), various voltages may be applied to one or more select lines 235 (e.g., to the gate of the transistors 230), to one or more bit lines 250 (e.g., to the drain of one or more transistors 230), to one or more word lines 265, to one or more select lines 245 (e.g., to the gate of the transistors 240), to one or more source lines 260 (e.g., to the source of the transistors 240), or to a bulk for the memory cells 205 (not shown) of the block 210. In some cases, each memory cell 205 of a block 210 may have a common bulk, the voltage of which may be controlled independently of bulks for other blocks 210.

In some cases, as part of a read operation for a memory cell 205, a positive voltage may be applied to the corresponding bit line 250 while the corresponding source line 260 may be grounded or otherwise biased at a voltage lower than the voltage applied to the bit line 250. In some examples, voltages may be concurrently applied to the select line 235 and the select line 245 that are above the threshold voltages of the transistor 230 and the transistor 240, respectively, for the memory cell 205, thereby activating the transistor 230 and transistor 240 such that a channel associated with the string 220 that includes the memory cell 205 (e.g., a pillar channel) may be electrically connected with (e.g., electrically connected between) the corresponding bit line 250 and source line 260. A channel may be an electrical path through the memory cells 205 in the string 220 (e.g., through the sources and drains of the transistors in the memory cells 205 of the string 220) that may conduct current under some operating conditions.

In some examples, multiple word lines 265 (e.g., in some cases all word lines 265) of the block 210—except a word line 265 associated with a page 215 of the memory cell 205 to be read—may concurrently be set to a voltage (e.g., VREAD) that is higher than the threshold voltage (VT) of the memory cells 205. VREAD may cause all memory cells 205 in the unselected pages 215 be activated so that each unselected memory cell 205 in the string 220 may maintain high conductivity within the channel. In some examples, the word line 265 associated with the memory cell 205 to be read may be set to a voltage, VTarget. Where the memory cells 205 are operated as SLC memory cells, VTarget may be a voltage that is between (i) VT of a memory cell 205 in an erased state and (ii) VT of a memory cell 205 in a programmed state.

When the memory cell 205 to be read exhibits an erased VT (e.g., VTarget>VT of the memory cell 205), the memory cell 205 may turn “ON” in response to the application of VTarget to the word line 265 of the selected page 215, which may allow a current to flow in the channel of the string 220, and thus from the bit line 250 to the source line 260. When the memory cell 205 to be read exhibits a programmed VT (e.g., VTarget<VT of the selected memory cell), the memory cell 205 may remain “OFF” despite the application of VTarget to the word line 265 of the selected page 215, and thus may prevent a current from flowing in the channel of the string 220, and thus from the bit line 250 to the source line 260.

A signal on the bit line 250 for the memory cell 205 (e.g., an amount of current below or above a threshold) may be sensed (e.g., by a sense component 170 as described with reference to FIG. 1), and may indicate whether the memory cell 205 became conductive or remained non-conductive in response to the application of VTarget to the word line 265 of the selected page 215. The sensed signal thus may be indicative of whether the memory cell 205 was in an erased state (e.g., storing a logic 1) or a programmed state (e.g., storing a logic 0). Though aspects of the example read operation above have been explained in the context of an SLC memory cell 205 for clarity, such techniques may be extended or altered and applied in the context of a multiple-level memory cell 205 (e.g., through the use of multiple values of VTarget corresponding to the different amounts of charge that may be stored in one multiple-level memory cell 205).

In some cases, as part of a program operation for a memory cell 205, charge may be added to a portion of the memory cell 205 such that current flow through the memory cell 205, and thus the corresponding string 220, may be inhibited when the memory cell 205 is later read. For example, charge may be injected into a charge trapping structure 120 as shown in memory cell 105-a of FIG. 1. In some cases, respective voltages may be applied to the word line 265 of the page 215 and the bulk of the memory cell 205 to be programmed such that a control gate 115 of the memory cell 205 is at a higher voltage than the bulk of the memory cell 205 (e.g., a positive voltage may be applied to the word line). Concurrently, voltages may be applied to the select line 235 and the select line 245 that are above the threshold voltages of the transistor 230 and the transistor 240, respectively, thereby activating the transistor 230 and the transistor 240, and the bit line 250 for the memory cell 205 to be programmed may be set to a relatively high voltage. This may cause an electric field such that electrons are pulled from the source of the memory cell 205 towards the drain. The electric field may also cause some of these electrons to be pulled through dielectric material 125 and thereby injected into the charge trapping structure 120 of the memory cell 205, through a process which may in some cases be referred to as tunnel injection.

In some cases, a single program operation may program some or all memory cells 205 in a page 215, as the memory cells 205 of the page 215 may all share a common word line 265 and a common bulk. For a memory cell 205 of the page 215 for which it is not desired to write a logic 0 (e.g., not desired to program the memory cell 205), the corresponding bit line 250 may be set to a relatively low voltage (e.g., ground), which may inhibit the injection of electrons into a charge trapping structure 120. Though aspects of the example program operation above have been explained in the context of an SLC memory cell 205 for clarity, such techniques may be extended and applied to the context of a multiple-level memory cell 205 (e.g., through the use of multiple programming voltages applied to the word line 265, or multiple passes or pulses of a programming voltage applied to the word line 265, corresponding to the different amounts of charge that may be stored in one multiple-level memory cell 205).

In some cases, as part of an erase operation for a memory cell 205, charge may be removed from a portion of the memory cell 205 such that current flow through the memory cell 205, and thus the corresponding string 220, may be uninhibited (e.g., allowed, at least to a greater extent) when the memory cell 205 is later read. For example, charge may be removed from a charge trapping structure 120 as shown in memory cell 105-a of FIG. 1. In some cases, respective voltages may be applied to the word line 265 of the page 215 and the bulk of the memory cell 205 to be erased such that a control gate 115 of the memory cell 205 is at a lower voltage than the bulk of the memory cell 205 (e.g., a positive voltage may be applied to the bulk), which may cause an electric field that pulls electrons out of the charge trapping structure 120 and into the bulk of the memory cell 205. In some cases, a single program operation may erase all memory cells 205 in a block 210, as the memory cells 205 of the block 210 may all share a common bulk.

In some techniques for manufacturing the memory architecture 200 (e.g., for manufacturing a memory die that includes one or more aspects of the memory architecture 200), one or more materials may be deposited over a substrate, such as a semiconductor substrate, and portions of the one or more materials may be removed in accordance with various patterning operations. In accordance with examples as disclosed herein, an array of cavities may be formed through a stack of material layers of a memory die to support aspects of the memory architecture 200, and conductors (e.g., conductive pillars, conductors associated with word lines 265, bit lines 250, select lines 235, select lines 245, source lines 260) may be formed at least in part by merging some of the cavities of the array. For example, such cavities may be sized in accordance with a relatively smallest feature that implements a subset of such cavities (e.g., for formation of a string 220), and the smallest associated feature may be formed using a first subset of the array of cavities. Conductors may be formed at least in part by merging two or more cavities of a second subset of the array of cavities. For example, patterns of cavities may be merged using a selective material removal, and a conductive material may be formed in the merged cavities to form conductive pillars. Such merging may allow for cavities for conductors to be formed with a cross-section that is greater than a cross-section of a single cavity. Accordingly, a uniform pattern of cavities can be formed to maintain processing and structural consistency across the memory die, and some cavities can be merged to provide larger openings for conductors to achieve a configured conductivity or resistivity value. Additionally, forming memory pillars and conductive pillars from the same array of cavities may result in improved processing efficiency and lowered production costs.

FIGS. 3 through 13 illustrate examples of fabrication operations that may support merged cavities for conductor formation in a memory die in accordance with examples as disclosed herein. For example, FIGS. 3 through 13 may illustrate aspects of sequences of operations for fabricating aspects of a material arrangement 300, which may be an example of implementing aspects of a memory architecture 200 described with reference to FIG. 2, among other types of memory architectures. Each of FIGS. 3 through 13 may illustrate aspects of the material arrangement 300 after different subsets of or alternatives of the fabrication operations for forming the material arrangement 300 (e.g., illustrated as a material arrangement 300-a after a first set of one or more manufacturing operations, as a material arrangement 300-b after a second set of one or more manufacturing operations, and so on). Each view of the figures may be described with reference to an x-direction, a y-direction, and a z-direction as illustrated, which may correspond to the respective directions described with reference to the memory architecture 200.

Some of the provided figures include section views that illustrate example cross-sections of the material arrangement 300. For example, in FIGS. 3 through 5, a view “SECTION A-A” may be associated with a cross-section in an xz-plane (e.g., in accordance with a cut plane A-A) through a portion of the material arrangement 300 associated with a set of cavities (e.g., including a cavity for at least one memory cell 205 along the z-direction, such as a string 220). Although the material arrangement 300 illustrates examples of some relative dimensions and quantities of various features, aspects of the material arrangement 300 may be implemented with other relative dimensions or quantities of such features in accordance with examples as disclosed herein.

Operations illustrated in and described with reference to FIGS. 3 through 13 may be performed by a manufacturing system, such as a semiconductor fabrication system configured to perform additive operations (e.g., deposition, epitaxy, bonding), subtractive operations (e.g., etching, trenching, planarizing, polishing), modifying operations (e.g., oxidizing, doping, reacting, converting), and supporting operations (e.g., masking, patterning, photolithography, aligning), among other operations that support the described techniques. In some examples, operations performed by such a manufacturing system may be supported by a process controller or its components as described herein.

FIG. 3 illustrates an example of a material arrangement 300 (e.g., as a material arrangement 300-a) after a first set of one or more manufacturing operations. As illustrated, the material arrangement 300-a may be associated with regions 301 (e.g., an array region, associated with one or more blocks 210), including cavities 305 that are associated with an array of memory cells 205, as well as regions 302 and regions 306 (e.g., contact regions, word line contact regions), including cavities 310 that may be associated with forming conductors to convey signals associated with accessing the memory cells 205. Each of the cavities 305 and 310 may extend through at least a portion of the material arrangement 300-a along the z-direction. In the material arrangement 300-a, at least some features of the regions 301 and regions 302 may be electrically isolated from one another, which may be supported by isolation regions 303 or isolation regions 304 (e.g., trench isolation regions), or various combinations thereof. In some examples, features associated with an isolation region 304 may be omitted from the material arrangement 300-a.

The first set of operations may include forming a layer of a material 325 (e.g., depositing the material 325 over a substrate 315), which may include a conductive material (e.g., a metal, a metal alloy, an electrically conductive ceramic such as tungsten silicide). In some examples, the layer of material 325 may support a ground node of a memory architecture 200, such as a source node of one or more blocks 210 (e.g., source lines 260, a common source). Although the material 325 is shown in the regions 302, 303, and 304, in some examples, at least a portion of the material 325 may be omitted from one or more of the regions 302, 303, or 304. Although the layer of material 325 may be formed in contact with the substrate 315, in some other examples, the material arrangement 300-a may include other materials or components between the layer of material 325 and the substrate 315. The substrate 315 may include or be otherwise associated with circuitry 320, which may include interconnection or routing circuitry (e.g., access lines, power routing lines), control circuitry (e.g., transistors, logic, decoding circuitry, addressing circuitry, aspects of a memory controller 180, a column decoder 150, a row decoder 160, a sense component 170, an input/output component 190), among other circuitry, which may include various conductor, semiconductor, or dielectric materials of the substrate 315, or between the layer of material 325 and the substrate 315, among other configurations. For example, the circuitry 320 may include an arrangement of complementary metal-oxide semiconductor (CMOS) transistors, or thin-film-transistors (TFTs), or any combination thereof at least in part between the substrate 315 and the layer of material 325, among others.

The first set of operations may also include forming a stack 330 (e.g., forming a stack of material layers, depositing a stack of material layers) over the substrate 315 (e.g., over the layer of material 325), which may support formation of various components that support the access of memory cells 205 (e.g., in regions 301). In some examples, the stack 330 may include a layer of a material 331, a layer of a material 332, a layer of a material 333, and a layer of a material 334. In some examples, the material 331 may be a semiconductor material (e.g., doped polysilicon, n+ doped polysilicon), which may support forming a channel portion of transistors 240. In some examples, each of the material 332, the material 333, and the material 334 may be a sacrificial material, at least a portion of which may be patterned and removed in later processing operations. In some examples, the material 332, the material 333, and the material 334 may be selected to support various techniques for differential processing (e.g., differential etching, high selectivity). For example, the material 332 may be a dielectric material (e.g., an oxide, an oxide of silicon, a liner oxide), the material 333 may be a semiconductor material (e.g., polysilicon), and the material 334 may be a dielectric material (e.g., an oxide, an oxide of silicon, a cap oxide) that may be the same as the material 332.

In some examples, the first set of operations may include operations that support forming etch stops in the stack 330 (e.g., vertical etch stops, to prevent material removal beyond the stack 330 in at least some regions of the material arrangement 300-a). For example, the first set of operations may include operations for forming cavities aligned (e.g., in an xy-plane) with locations of the cavities 305, and forming trenches aligned along locations of the isolation regions 303. In some examples, such trenches may be connected with other such trenches (e.g., along the x-direction) to provide a trench isolation around each portion of the material arrangement 300-a that is associated with a block 210 (e.g., enclosing an area in an xy-plane associated with a block 210, enclosing regions 301 or some portion thereof). Such cavities and trenches may extend at least in part through the layer of the material 321, supporting the formation of a material 335 (e.g., oxidized doped polysilicon, which may include oxidizing the material 331) along the bottom and sidewalls of the cavities and trenches. In some examples, after forming etch stop features in the stack 330, the first set of operations may include forming (e.g., depositing, oxidizing) a layer of a material 336 and a layer of a material 337 over the stack 330. The material 336 may be an oxide material (e.g., an oxide of silicon), and the material 337 may be a semiconductor material (e.g., polysilicon). In some examples, the material 336 may be a sacrificial material (e.g., with portions removed in one or more later operations), and the material 337 may support formation of one or more transistor structures (e.g., as part of a channel of transistors 240 of the memory architecture 200).

The first set of operations also may include forming a stack 340 (e.g., forming a stack of material layers, depositing a stack of material layers), which may include various formation operations. For example, forming the stack 340 may include forming alternating layers of a material 341 and a material 342 (e.g., in accordance with alternating material deposition or other formation operations). In some examples, the material 341 may include a dielectric material (e.g., an oxide, a tier oxide, an oxide of silicon), which may provide electrical isolation between features of the material arrangement 300-a (e.g., between pages 215, between word lines 265, along the z-direction). The material 342 may include various materials that are different than the material 341 (e.g., a nitride material, a nitride of silicon), and may be a sacrificial material (e.g., to support subsequent differential etching procedures). Although the stack 340 is illustrated with twenty-five layers (e.g., thirteen layers of the material 341 and twelve layers of the material 342), a stack 340 in accordance with examples as disclosed herein may include any quantity of layers of each of two or more materials (e.g., tens of layers, hundreds of layers, and so on), including as few as one layer of the material 342.

The first set of operations also may include operations for forming the cavities 310. For example, the first set of operations may include operations (e.g., dry etching operations, photolithography operations) for forming cavities 310 through the stack 340 and the stack 330 in the regions 302 and the regions 306 (e.g., exposing electrical contacts, such as conductive material portions, associated with the circuitry 320). In some examples, one or more cavities 310 may be aligned along the y-direction, or another direction, with a corresponding set of cavities 305 (e.g., a row of cavities 305 along the x-direction, or other direction). In some examples, cavities 305 and 310 may be formed in a continuous pattern (e.g., without a discontinuity along one or more directions in an xy-plane), which may include a region 306 being directly adjacent to a region 301, among other examples.

Forming the cavities 310 and the cavities 305 may support forming contacts associated with the one or more cavities 310 (e.g., of a region 302) being coupled with a bit line 250 formed above (e.g., along the z-direction) the corresponding set of cavities 305. However, cavities 310 may be formed in a region 302 or a region 306 for other purposes, and accordingly may be arranged in various other configurations. The cavities 310 may be formed via openings (e.g., cross-sectional openings, openings in an xy-plane) that are non-overlapping with one another (e.g., in an xy-plane). In some examples, openings for forming cavities 310 may have a same or similar cross-section (e.g., size, shape) as openings for forming cavities 305. Additionally, or alternatively, openings for forming cavities 310 may be formed in a same or similar pattern (e.g., a honeycomb pattern, which may include the same or similar spacing between openings) as openings for forming cavities 305. Forming cavities 310 may be associated with forming (e.g., exposing) sidewalls of one or more materials of the stack 340 and of the stack 330, and such sidewalls may have a shape that is tapered along the z-direction.

Although, in some examples, the cavities 310 may be formed through the stack 340 and the stack 330 in a single material removal operation, in some other examples, such cavities may be formed using a sequence of material removal operations. For example, for each cavity 310, a respective first cavity may be formed through at least the stack 330 and, in some examples, one or both of the material 336 or the material 337, and each first cavity may be filled with a sacrificial material (e.g., sacrificial carbon, with or without a liner material, or a stack of different materials). In some examples, such operations may be performed before forming the stack 340. A respective second cavity, coincident (e.g., aligned) with the respective first cavity (e.g., coaxial along the z-direction, in accordance with an alignment tolerance in an xy-plane), may be formed through at least a subset of material layers of the stack 340 (e.g., before forming another subset of material layers of the stack 340), and the second cavity may be filled with a sacrificial material (e.g., coincident with previously-formed sacrificial material, over which another subset of material layers of the stack 340 may be formed). Such a sequence may be repeated for any quantity of iterations and a single, collective cavity 310 may be formed by removing the sacrificial material from the earlier cavity fill operations.

The first set of operations also may include operations for forming the cavities 305. For example, the first set of operations may include operations (e.g., dry etching operations, photolithography operations) for forming cavities 305 through the stack 340 and through at least a portion of the stack 330 in regions 301 (e.g., exposing a portion of the material 325, using the material 325 as a cavity etch stop). Cavities 305 may be formed in a pattern, which may include a staggering of rows to improve density of cavities 305 (e.g., in an xy-plane). The cavities 305 may be formed via openings that are non-overlapping with one another, and forming cavities 305 may be associated with forming sidewalls of one or more materials of the stack 340 and of the stack 330. In some examples, one or more operations associated with forming cavities 305 may be performed concurrently (e.g., the one or more operations may occur during overlapping durations or during a same duration or process) with corresponding operations associated with forming cavities 310 (e.g., etching operations, sacrificial material deposition operations). For example, the cavities 305 and the cavities 310 may be formed using a similar pattern (e.g., etching patterns), and may have similar dimensions (e.g., opening sizes, shape, depth).

Although, in some examples, cavities 305 may be formed through at least the stack 340 in a single material removal operation, in some other examples, cavities 305 may be formed using a sequence of material removal operations. For example, for each cavity 305, a respective first cavity may be formed through a first subset of material layers of the stack 340, and the first cavity may be filled with a sacrificial material (e.g., before forming a second subset of material layers of the stack 340). A respective second cavity, aligned with the respective first cavity, may be formed through a second subset of material layers of the stack 340, and the second cavity may be filled with a sacrificial material. Such a sequence may be repeated for any quantity of iterations and a single, collective cavity 305 may be formed by removing the sacrificial material from the earlier cavity fill operations.

In some examples, each cavity 305 and cavity 310 may be filled with a sacrificial material 351 (e.g., sacrificial carbon, or a different material). In some cases, each cavity 310 may be filled with a sacrificial material 351 during one or more filling operations that also includes forming sacrificial material in each cavity 305 (e.g., concurrently). In some examples, after forming the cavities 310, the first set of operations may include forming a layer of a material 355 (e.g., a dielectric material, an oxide of silicon) over the stack 340, which may provide a barrier that protects the cavities 305 or cavities 310 during subsequent operations (e.g., that may involve removing sacrificial material 351 from a subset of cavities to perform subsequent operations).

The cavities 305 may be involved in various operations that support forming memory cells (e.g., memory cells 105, memory cells 205, memory cells of a string 220) associated with the cavities 305. For example, the sacrificial material 351 may be removed from each cavity 305, and at least a material 361 and a material 362, and, in some examples, a material 363 may be formed (e.g., deposited, oxidized) in the formed cavities associated with the cavities 305 to form pillars 307 (e.g., cell pillars, memory pillars, corresponding to a string 220) The cavities 305 may extend along the z-direction, such that a pillars 307 formed in a cavity 305 may have extents along the z-direction. The material 361 may support a charge-trapping function of memory cells 205 and, in various examples, may include one or more layers of material. In some examples, the material 361 may include a first layer (e.g., a dielectric layer, an oxide layer, an oxide of silicon) in contact with walls of the formed cavities, which may support first dielectric materials 125 of a string of memory cells 205, a second layer (e.g., a charge-trapping layer, a nitride layer, a nitride of silicon) over the first layer, which may support charge trapping structures 120 of the string of memory cells 205, and a third layer (e.g., a dielectric layer, an oxide layer, an oxide of silicon) over the second layer, which may support second dielectric materials 125 of the string of memory cells 205. The material 362 may be a semiconductor material (e.g., polysilicon, in contact with the material 361 or third layer thereof), which may support channel portions of the string of memory cells 205 (e.g., between respective first nodes 130 and second nodes 135). The material 363 may be a dielectric material (e.g., silicon oxide, in contact with the material 362) which, in some examples, may fill a remainder of the cavities. In some examples, a portion of at least the material 363 may be removed (e.g., recessed) from the top of the cavities 305 and an additional portion of the material 362 may be formed (e.g., deposited, oxidized) to fill the top portions of the cavities 305 (e.g., in a plug formation operation). In some examples, after forming the pillars 307, the first set of operations may include forming a layer of a material 365 (e.g., a dielectric, material an oxide of silicon) over the stack 340, which may provide a barrier that protects the pillars 307 during subsequent operations.

The first set of operations also may include various operations (e.g., dry etching operations, photolithography operations) for forming trenches 370 through the stack 340 and through at least a portion of the stack 330 along the isolation regions 303 (e.g., exposing a portion of the material 325, using the material 325 as a trench etch stop). In some examples, one or more operations associated with forming trenches 370 for the isolation regions 303 may be performed concurrently with corresponding operations associated with forming cavities for the pillars 307 (e.g., etching operations, sacrificial material deposition operations). Although, in some examples, trenches 370 may be formed through at least the stack 340 in a single material removal operation, in some other examples, trenches 370 may be formed using a sequence of material removal operations. For example, for each isolation region 303, a respective first trench may be formed through a first subset of material layers of the stack 340, and the first trench may be filled with a sacrificial material (e.g., before forming a second subset of material layers of the stack 340). A respective second trench, aligned with the respective first trench, may be formed through a second subset of material layers of the stack 340, and the second trench may be filled with a sacrificial material. Such a sequence may be repeated for any quantity of iterations and a trench 370 may be formed by removing the sacrificial material from the earlier trench fill operations. In some examples, forming trenches 370 may involve removing at least a portion of the material 355, or the material 365, from the isolation regions 303.

Opening the trenches 370 may support formation of structures associated with the pillars 307. For example, voids 371 may be formed via the trenches 370, which may include removing (e.g., via a wet etching operation) exposed portions of the material 332, the material 333, the material 334, the material 336, and the material 361. In some examples, such operations may be preceded by forming a liner material (not shown) on surfaces of the stack 340 associated with the trenches 370, which may prevent removal of the material 341 and the material 342 during such operations. A material 375 may be formed in the voids 371, which may further support forming aspects of transistors 240. For example, the material 375 may include a semiconductor material (e.g., a doped polysilicon material, an n+ doped polysilicon material), which may be the same as the material 331. In some examples, after forming the material 375, a liner along the trench 370 may be removed, and exposed surfaces of the material 331 and the material 375 may be oxidized to form additional portions of the material 335.

In some examples, forming word lines 265 in the material arrangement 300-a may involve forming voids by removing portions of the material 342 from the stack 340 in the regions 301, and forming one or more conductive materials in the formed voids. However, with some techniques for forming such voids, the extents of the removal of the material 342 (e.g., along the x-direction, along the y-direction) may be indeterminate or otherwise difficult to control due to variations in material removal rates and different material removal dimensions. Thus, in some examples, voids may extend into regions 302, among other regions (e.g., between adjacent regions 301 that are intended to be electrically isolated), which may allow conductive materials to be adversely formed near the cavities 310, or between cavities 310 and cavities 305, among other features of the material arrangement that are intended to be electrically isolated. Although, in some examples, cavities 310 may be located relatively far from trenches 370 to avoid adverse coupling with the conductive material, among other techniques to compensate for an indeterminate or otherwise variable extent of voids and conductor deposition, such techniques may be associated with relatively inefficient utilization of an area (e.g., in an xy-plane) of the material arrangement 300-a.

In some examples, to form features of the isolation regions 304, the first set of operations may include operations (e.g., dry etching operations, photolithography operations) for forming trenches 380 through at least the stack 340 and, in some examples, through the stack 330 and the layer of material 325, along the isolation regions 304. In some examples, one or more operations associated with forming trenches 380 for the isolation regions 304 may be performed concurrently with corresponding operations associated with forming cavities for the cavities 310 (e.g., etching operations, sacrificial material deposition operations). Although, in some examples, trenches 380 may be formed in a single material removal operation, in some other examples, trenches 380 may be formed using a sequence of material removal operations, in accordance with examples as disclosed herein (e.g., as described with reference to forming cavities 310). After forming trenches 380, a material 381, which may include be dielectric material (e.g., an oxide, an oxide of silicon), may be formed (e.g., deposited, oxidized) in the trenches 380.

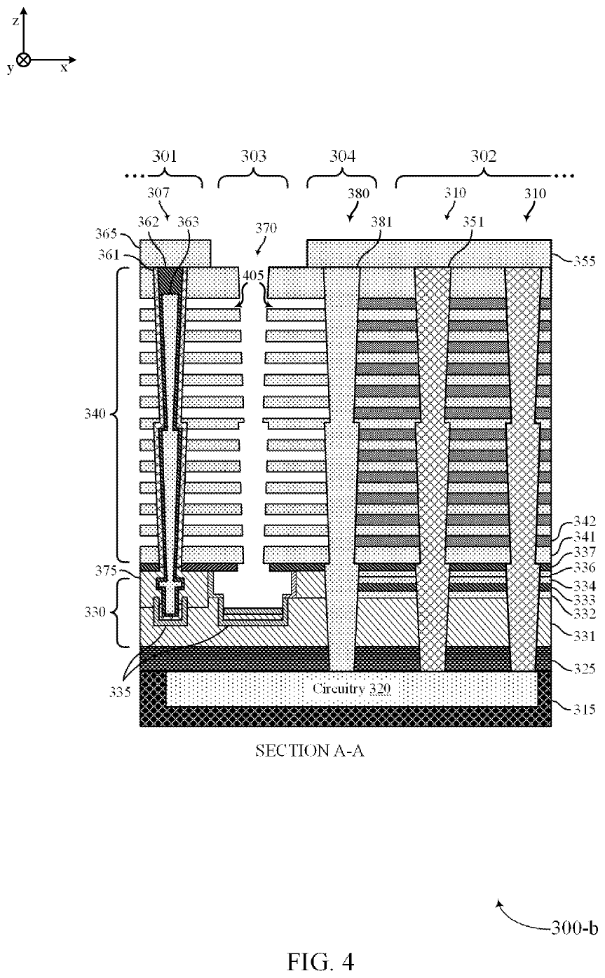

FIG. 4 illustrates the material arrangement 300 (e.g., as a material arrangement 300-b) after a second set of one or more manufacturing operations, as a cross-sectional side view (e.g., relative to the cut plane A-A). The second set of operations may include operations (e.g., wet etching operations, exhuming operations) that support forming word lines 265 in the regions 301. For example, the second set of operations may include forming voids 405 between layers of the material 341 by removing the material 342 from portions of the stack 340 (e.g., in the regions 301). Forming the voids 405 may expose portions of the pillars 307 (e.g., exposing sidewalls of the material 361 between layers of the material 341), which may remain in contact with the material 341 and support the material 341 across the voids 405 (e.g., along the z-direction) for the formation of word lines (e.g., word lines 265), among various structures of the memory architecture 200. In some examples, the voids 405 may extend as far as the isolation regions 304, which may include exposing sidewalls of the material 381 between the layers of the material 341. However, by including isolation regions 304, the voids 405 may not extend into the regions 302 (e.g., such that layers of the material 342 of the stack 340 may remain in the regions 302), which may prevent the formation of conductive materials in the regions 302 during formation of the word lines 265.

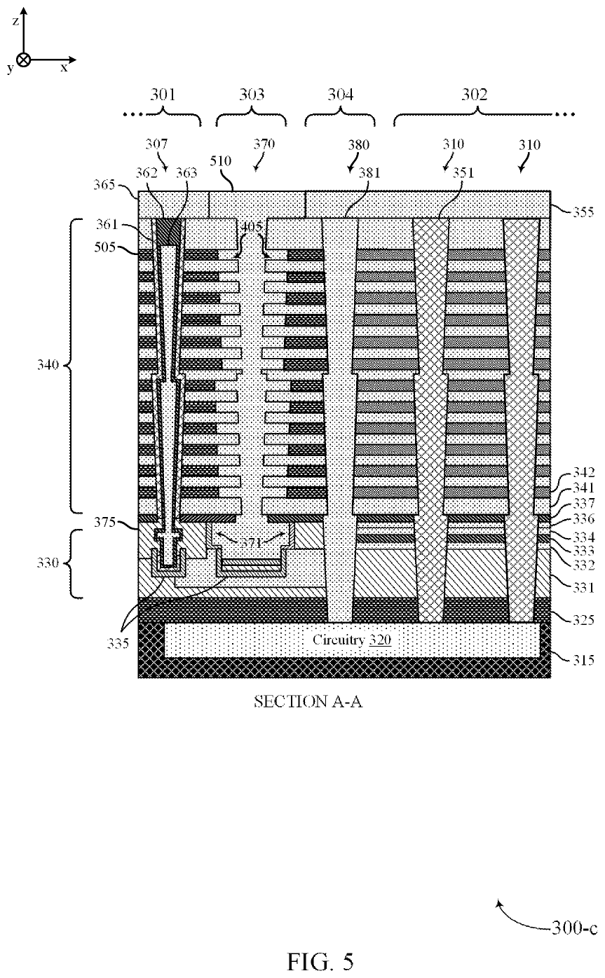

FIG. 5 illustrates the material arrangement 300 (e.g., as a material arrangement 300-c) after a third set of one or more manufacturing operations, as a cross-sectional side view (e.g., relative to the cut plane A-A). The third set of operations may include further operations (e.g., one or more deposition operations, metal fill operations, etching operations) that support forming word lines 265 between layers of the material 341 (e.g., in portions of the voids 405). For example, the third set of operations may include forming (e.g., depositing) a material 505 in the voids 405 (e.g., between layers of material 341), which may include forming the material 505 in contact with or otherwise electrically coupled with the pillars 307 (e.g., in contact with the material 361). The material 505 may include one or more conductive materials, such as tungsten, which may be the same as the material 325. In some examples, forming the material 505 may include forming (e.g., depositing, oxidizing) a dielectric material (e.g., aluminum oxide) in contact with the pillars 307 (e.g., in contact with the material 361, before depositing one or more conductive materials), which may support a dielectric function of memory cells 205 (e.g., a dielectric material 125). Portions of the material 505 may be removed (e.g., in a recess etch operation) from portions of the voids 405 to provide electrical isolation between word lines 265.

The third set of operations also may include operations (e.g., one or more deposition operations, one or more oxidation operations) that support forming an electrical isolation in the isolation regions 303 based at least in part on forming (e.g., depositing, oxidizing) a material 510 in regions 303 (e.g., in the trenches 370 and at least some portion of the voids 405). The material 510 may be a dielectric material (e.g., an oxide, an oxide of silicon) which may be the same as the material 355 or the material 365, among other materials of the material arrangement 300.

The third set of operations may be followed by other operations to support aspects of the memory architecture 200, such as forming bit lines 250 coupled with the strings 220 (e.g., conductive lines over the material arrangement 300-c, which may be aligned along the x-direction and operable for coupling between the material 362 and a conductor), and forming vertical contacts (e.g., vertical conductors) coupled with each of the word lines 265 (e.g., contacts electrically coupled with respective layers of material 505), among other features.

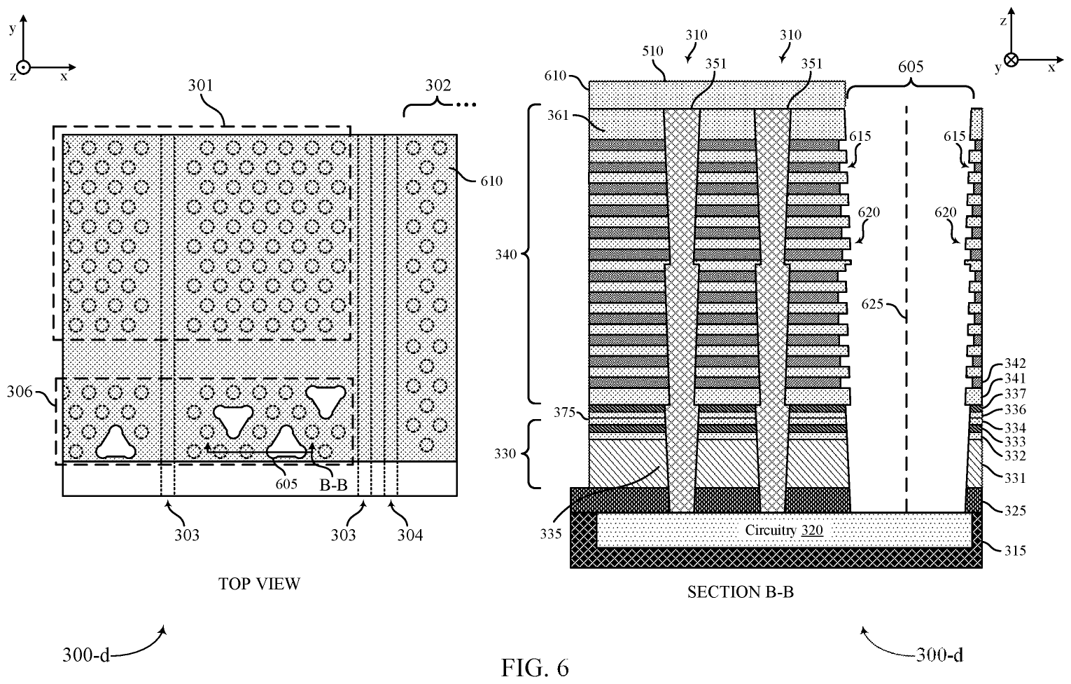

FIGS. 6 through 9 illustrate a first alternative for implementing merged cavities for conductor formation in a memory die in accordance with examples as disclosed herein (e.g., implementing a full merge of cavities 310). Each of FIGS. 6 through 9 may illustrate aspects of the material arrangement 300 after different subsets of the fabrication operations for forming the material arrangement 300 in accordance with the first alternative (e.g., after the third set of operations). In FIGS. 6 through 9, a view “SECTION B-B” may be associated with a cross-section in an xz-plane (e.g., in accordance with a cut plane B-B) through a portion of the material arrangement 300 associated with a set of cavities 310 (e.g., including multiple cavities 310 for formation and isolation of a conductor). Although aspects of the first alternative for implementing merged cavities for conductor formation are illustrated in the region 306, similar techniques may be implemented using cavities 310 of a region 302, among other regions of a memory die, to form conductors using merged cavities 310.

FIG. 6 illustrates the material arrangement 300 (e.g., as a material arrangement 300-d) after a fourth set of one or more manufacturing operations, as a top view and as a cross-sectional side view (e.g., relative to the cut plane B-B). The fourth set of operations may include operations (e.g., etching operations, wet etching operations, recessing operations) that support forming merged cavities 605 at least in part by merging multiple cavities 310 (e.g., fully merging along the z-direction).

The fourth set of operations may include operations (e.g., masking operations, photolithography operations, patterning operations) that support forming a mask 610 (e.g., a masking material) over pillars 307 and at least some cavities 310 (e.g., in the region 302 and the region 306). A mask 610 may protect pillars 307 and at least some cavities 310, among other intervening features, from being affected (e.g., etched) by subsequent operations (e.g., etching operations, wet etching operations). Forming the mask 610 may include patterning operations to expose regions (e.g., in an xy-plane) corresponding to sets of cavities 310 that are to be merged. For example, the mask 610 may include a masking material (e.g., a hardmask) formed in a pattern over the stack 340, such that the masking material does not cover locations of cavities 310 to be merged. In various examples, a boundary of the mask 610 (e.g., a boundary of an opening, in an xy-plane) may be coincident with boundaries (e.g., openings) of cavities 310, or a boundary of the mask 610 may be non-coincident with boundaries of cavities 310. For example, a boundary of the mask 610 may be wider than (e.g., and enclose) the cavities 310 that are to be merged, which may support a relatively larger merged cavity.

In some cases, different patterns for forming the mask 610 may be employed. For example, a quantity or pattern of cavities 310 exposed (e.g., grouped) to form the merged cavities 605 may vary between configurations. Additionally, or alternatively, a quantity or pattern of cavities 310 that remain masked between exposed locations for the merged cavities 605 may vary between configurations. Such techniques may result in different spacings between merged cavities 605 (e.g., for different amounts of electrical isolation), or different amounts (e.g., cross-sections) of conductive materials formed within merged cavities 605. Accordingly, a uniform pattern of cavities 310 can be formed to maintain processing and structural consistency across the memory die, and different sizes of and spacing between merged cavities 605 may be implemented to achieve desired conductivity or resistivity values.

The fourth set of operations may include merging (e.g., fully merging) multiple cavities 310 by removing the sacrificial material 351, as well as at least the material 341 and the material 342 from portions of the stack 340 (e.g., along the z-direction, between cavities 310), among other materials (e.g., materials 336 and 337, one or more materials of the stack 330, or a combination thereof, where applicable). Merging cavities 310 to form a merged cavity 605 may form a contiguous region with an absence of materials between the at least two cavities 310. In some examples, forming the merged cavities 605 may include removing materials to expose the circuitry 320 (e.g., a conductor of the circuitry 320), or a portion of the material 325 (e.g., where a portion of the material 325 in at least the region 306 or other region is part of a distribution layer or other electrical node, which may not involve exposing a conductor of the circuitry 320).

In some examples, forming the merged cavities 605 may involve operations (e.g., wet etching operations, recessing operations) that may recess the material 342 and expose sidewalls 615 of the material 342 between layers of the material 341. As such, the fourth set of operations may result in forming one or more projections 620 of the material 341 towards an axis 625 of a respective merged cavity 605 that extends along the z-direction (e.g., towards the axis 625 along the x-direction, or along other directions in an xy-plane).

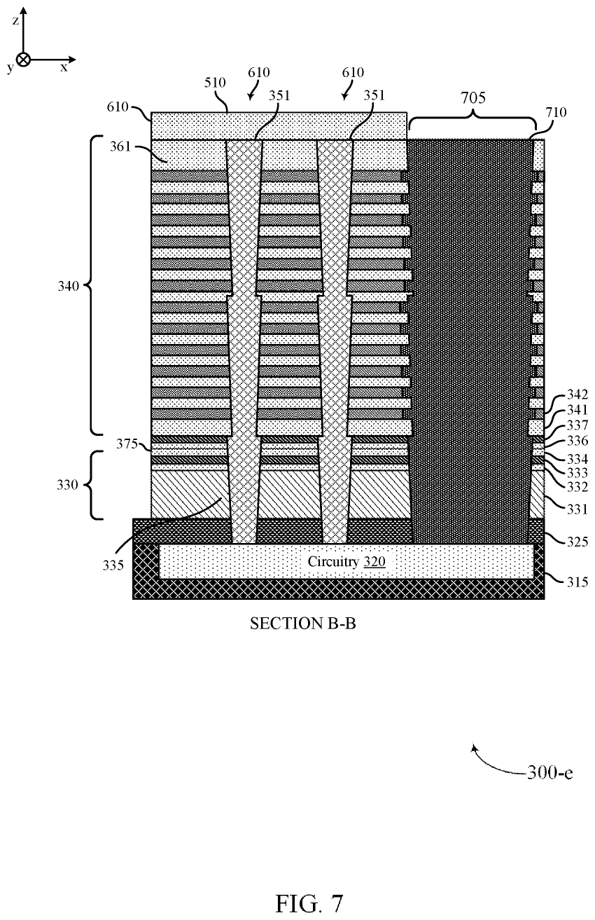

FIG. 7 illustrates the material arrangement 300 (e.g., as a material arrangement 300-e) after a fifth set of one or more manufacturing operations, as a cross-sectional side view (e.g., relative to the cut plane B-B). The fifth set of operations may include operations (e.g., one or more deposition operations, metal fill operations) that support forming conductors 705 at least in part by forming a material 710 in the merged cavities 605. For example, the third set of operations may include forming (e.g., depositing) the material 710 in the merged cavities 605 (e.g., through at least the stack 340 and, in some examples, through the stack 340, where applicable). The material 710 may include one or more conductive materials, (e.g., a metal, a metal alloy, an electrically conductive ceramic such as tungsten silicide, a deposition of an electrode layer followed by a bulk fill deposition of a conductor), which may be the same as the material 325, or the material 505, or any combination thereof. The cavities 310 and the merged cavities 605 may extend along the z-direction, such that a conductor 705 may have extents along the z-direction. The extents along the z-direction may at least partially overlap with the extents along the z-direction associated with a pillar 307 formed in a cavity 305.

Forming the material 710 may include depositing the material 710 within voids formed by recession of the material 342. For example, voids may be formed by the removal of material (e.g., the material 342) as a result of an omnidirectional etch (e.g., a wet etch). The conductor 705 may accordingly have one or more projections (e.g., in contact with the sidewalls 615) that extend away from the axis 625 (e.g., along the x-direction, or along other directions in an xy-plane). In some examples, such techniques may include forming the material 710 in contact with or otherwise electrically coupled with the material 325 (e.g., where a portion of the material 325 in the region 306 or other region is part of a distribution layer or other electrical node, which may not involve forming the material 710 in contact with a conductor of the circuitry 320). Additionally, or alternatively, such techniques may include forming the material 710 electrically isolated from the material 325, or forming the material 710 in contact with or otherwise electrically coupled with the circuitry 320 (e.g., in a region where the material 325 is omitted). Forming the conductor 705 in contact with or otherwise electrically coupled with the circuitry 320 may electrically couple the conductor with one or more transistor structures (e.g., transistors of the circuitry 320, transistors formed at least in part by a doped portion of the substrate 315).

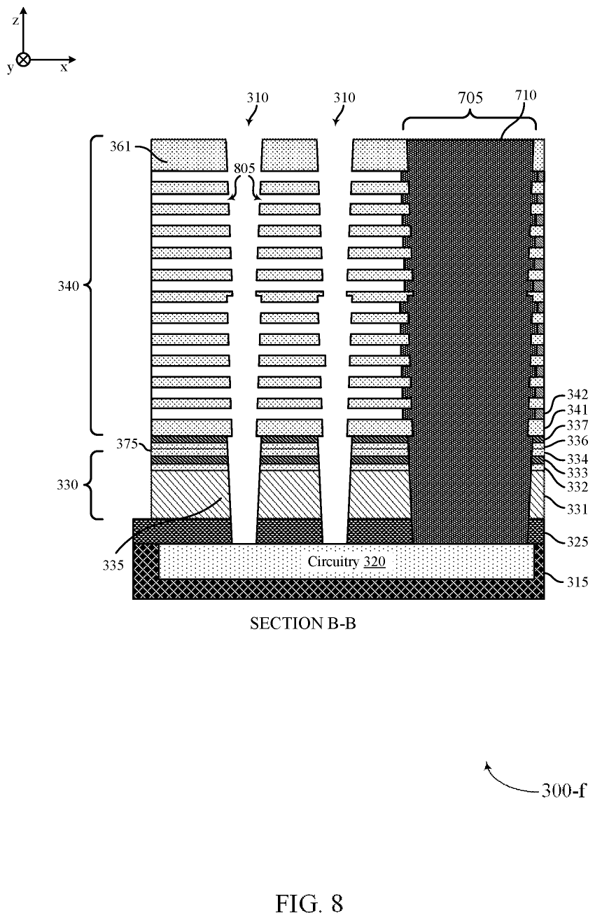

FIG. 8 illustrates the material arrangement 300 (e.g., as a material arrangement 300-f) after a sixth set of one or more manufacturing operations, as a cross-sectional side view (e.g., relative to the cut plane B-B). The sixth set of operations may include operations (e.g., etching operations, wet etching operations, recessing operations) that support forming an electrical isolation between conductors 705. For example, the sixth set of operations may include removing the mask 610, as well as the sacrificial material 351 from cavities 310 that are not associated with the conductors 705. The sixth set of operations may also include removing portions of the material 342 to form voids 805 (e.g., between layers of the material 341 through at least a portion of the region 306, among other regions), which may expose portions of the conductor 705 (e.g., sidewalls of the material 710 between layers of the material 341).

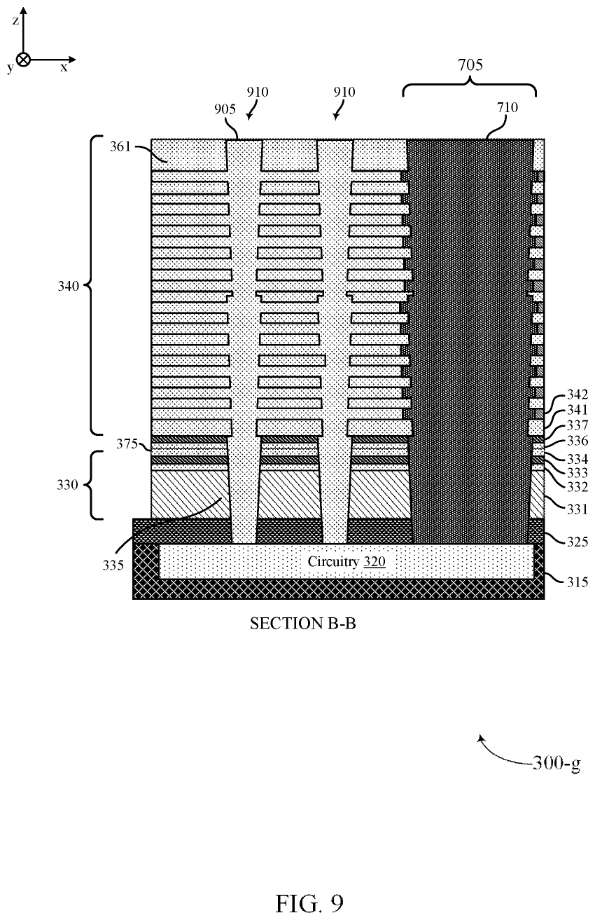

FIG. 9 illustrates the material arrangement 300 (e.g., as a material arrangement 300-g) after a seventh set of one or more manufacturing operations, as a cross-sectional side view (e.g., relative to the cut plane B-B). The seventh set of operations may include operations (e.g., one or more deposition operations, one or more oxidation operations) that support forming an electrical isolation between conductors 705, among other features. For example, the seventh set of operations may include forming a material 905 in cavities 310 and voids 805. For example, the seventh set of operations may include forming (e.g., depositing) the material 905 in at least some cavities 310 not used for forming conductors 705, which may include forming the material 905 in contact with exposed portions of the material 710. The material 905 may be the same as the material 341, the material 336, the material 355, the material 365, the material 381, the material 510, or any combination thereof, among other materials of the material arrangement 300, which may be a dielectric material (e.g., an oxide, an oxide of silicon). The material 905 (e.g., including isolation pillars 910 associated with cavities 310 filled with the material 905) may provide electrical isolation between the conductors 705 and other features of the material arrangement 300.

The conductors 705 may support coupling between various features of a memory architecture 200. For example, conductors 705 may be implemented as part of an electrical coupling between circuitry 320 and any one or more of a word line 265 (e.g., a portion of material 505), a source line 260, a select line 245, a bit line 250, or a select line 235, among other nodes of the memory architecture 200, which may support implementing the circuitry 320 for operations of the memory architecture 200. Such an electrical coupling may involve formation of one or more conductive materials, not shown, between the respective components (e.g., over or otherwise through a region 303, above or below a stack 340, where applicable, among other examples). Additionally, or alternatively, conductors 705 may be implemented to support electrical coupling of other elements of a material arrangement 300.

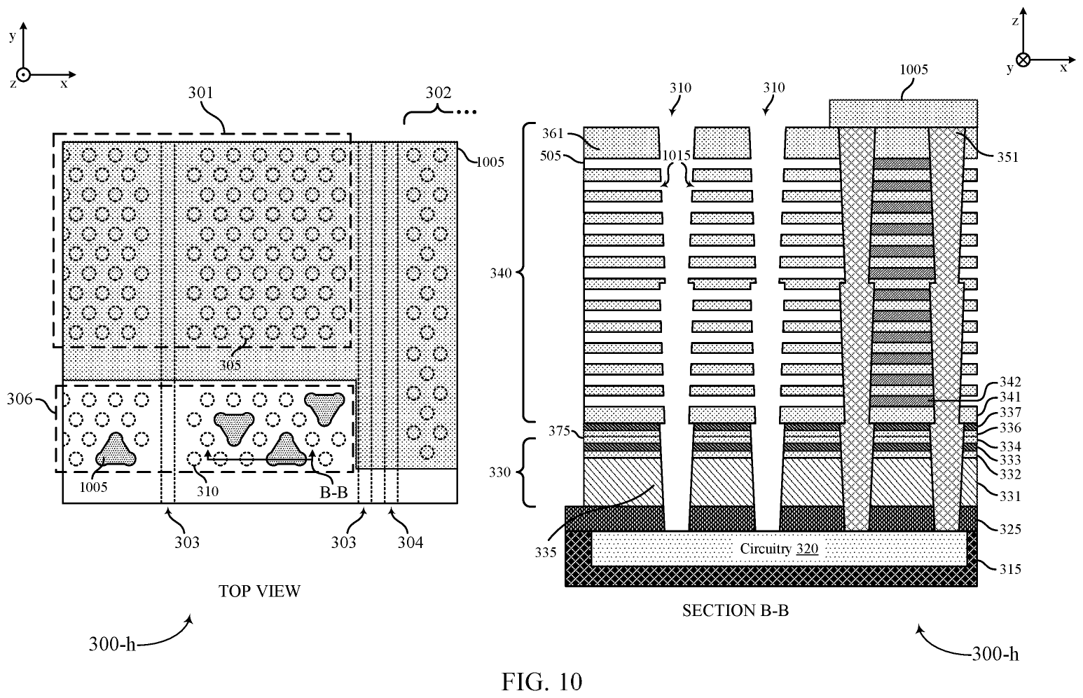

FIGS. 10 through 13 illustrate a second alternative for implementing merged cavities for conductor formation in a memory die in accordance with examples as disclosed herein (e.g., implementing a partial merge of cavities 310 for forming conductors). Each of FIGS. 10 through 13 may illustrate aspects of the material arrangement 300 after different subsets of the fabrication operations for forming the material arrangement 300 in accordance with the second alternative (e.g., after the third set of operations). In FIGS. 10 through 13, a view “SECTION B-B” may be associated with a cross-section in an xz-plane (e.g., in accordance with a cut plane B-B) through a portion of the material arrangement 300 associated with a set of cavities 310 (e.g., including multiple cavities 310 for formation and isolation of a conductor). Although aspects of the second alternative for implementing merged cavities for conductor formation are illustrated in the region 306, similar techniques may be implemented using cavities 310 of a region 302, among other regions of a memory die, to form conductors using merged cavities 310 in the region 302.

FIG. 10 illustrates the material arrangement 300 (e.g., as a material arrangement 300-h) after an eighth set of one or more manufacturing operations, as a top view and as a cross sectional side view (e.g., relative to the cut plane B-B). The eighth set of operations may include operations (e.g., etching operations, wet etching operations, recessing operations) that support forming isolation regions.

The eighth set of operations may include operations (e.g., masking operations, photolithography operations, patterning operations) that support forming a mask 1005 (e.g., a masking material). Forming the mask 1005 may include patterning operations to mask regions corresponding to cavities 310 to be merged to form conductors as well as at least some cavities 305 and 310 (e.g., in the region 301 and the region 302), while exposing regions corresponding to cavities 310 for forming electrical isolation regions. For example, the mask 1005 may include a masking material (e.g., a hardmask) formed in a pattern over the stack 340, such that the masking material covers locations of cavities 310 in the region 306 to be merged to form conductors. In some cases, different patterns for forming the mask 1005 may be employed. For example, a quantity or pattern of cavities 310 exposed to form isolation regions may vary between configurations. Additionally, or alternatively, a quantity or pattern of cavities 310 that remain masked by the mask 1005 may vary between configurations. Such techniques may result in different spacings between masked cavities 310 (e.g., for different amounts of electrical isolation), and different amounts of conductive materials formed within cavities 310 that are later merged to form conductors. Accordingly, a uniform pattern of cavities 310 can be formed to maintain processing and structural consistency across the memory die, and different sizes and spacing between of cavities 310 to be merged may be formed to achieve configured conductivity or resistivity values.

The eighth set of operations may include operations (e.g., etching operations, wet etching operations, recessing operations) that support forming electrical isolation regions between cavities 310 to be merged. For example, the eighth set of operations may include removing the sacrificial material 351 from cavities 310 that are not to be merged to form conductors. The eighth set of operations may also include removing portions of the material 342 to form voids 1015 (e.g., between layers of the material 341 through at least a portion of the region 306, among other regions), which may expose portions of the sacrificial material 351 corresponding to the cavities 310 that are masked by the mask 1005 (e.g., sidewalls of the sacrificial material 351 between layers of the material 341).

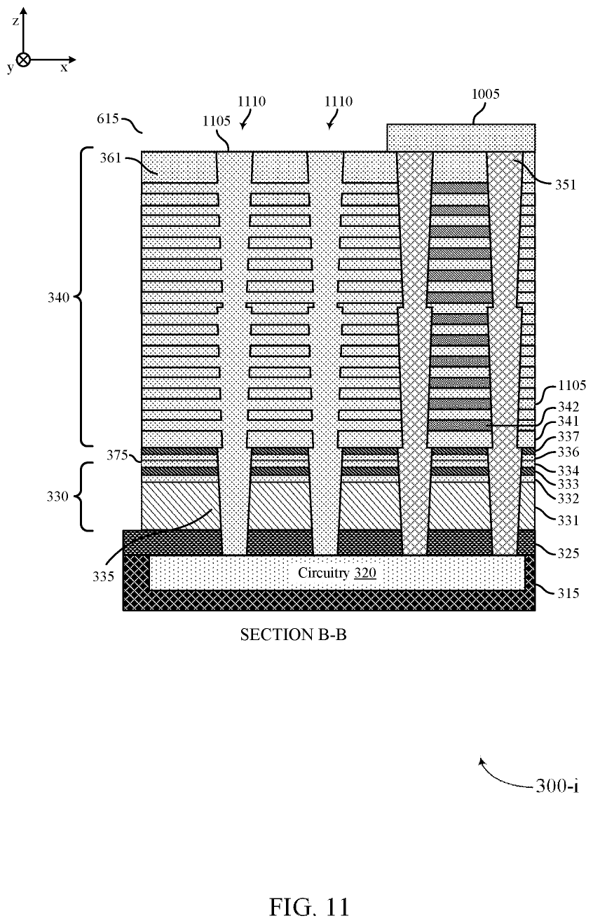

FIG. 11 illustrates the material arrangement 300 (e.g., as a material arrangement 300-i) after a ninth set of one or more manufacturing operations as a cross-sectional side view (e.g., relative to the cut plane B-B). The ninth set of operations may include further operations (e.g., one or more deposition operations, one or more oxidation operations) that support forming electrical isolation (e.g., including isolation pillars 1110) between cavities 310 to be merged for conductor formation. For example, the ninth set of operations may include forming a material 1105 in cavities 310 and voids 1015. For example, the ninth set of operations may include forming (e.g., depositing) the material 1105 in at least some the cavities 310 that are not to be merged, which may include forming the material 1105 in contact with exposed portions of the sacrificial material 351. The material 1105 may be the same as the material 341, the material 336, the material 355, the material 365, the material 381, the material 510, or any combination thereof, among other materials of the material arrangement 300 which may be a dielectric material (e.g., an oxide, an oxide of silicon). The isolation pillars 1110 may provide electrical isolation between the conductors that are to be formed in the merged cavities 310 and other features of the material arrangement 300.

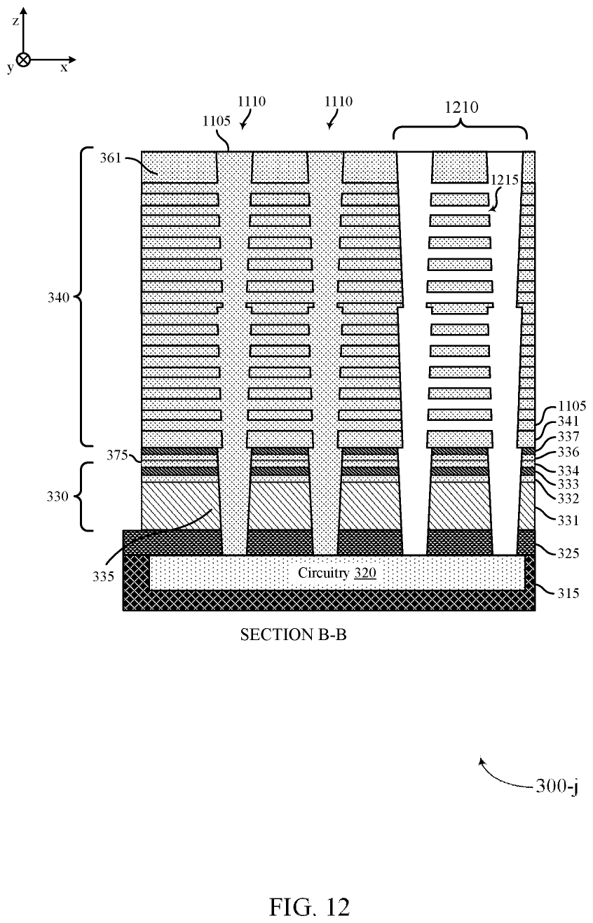

FIG. 12 illustrates the material arrangement 300 (e.g., as a material arrangement 300-j) after a tenth set of one or more manufacturing operations as a cross-sectional side view (e.g., relative to the cut plane B-B). The tenth set of operations may include operations (e.g., etching operations, wet etching operations, recessing operations) that support forming merged cavities 1210 at least in part by merging multiple cavities 310 (e.g., partially merging the cavities along the z-direction).

The tenth set of operations may include merging multiple cavities 310 by removing the mask 1005 and removing the sacrificial material 351 from cavities 310 to be merged for conductor formation. The tenth set of operations may also include removing at least the material 342 from portions of the stack 340 (e.g., between layers of the material 341 within the region 306) to form voids 1215 between layers of the material 341 (e.g., to form a partial merge between cavities 310). However, in some other examples (not shown), the tenth set of operations may also include removing the material 341, among other materials, to form a fully-merged cavity (e.g., without intervening portions of the material 341 or other materials). Merging cavities 310 to form a merged cavity 1210 may form a contiguous region with an absence of materials between the at least two cavities 310. In some examples, forming the merged cavities 1210 may include removing materials to expose the circuitry 320 (e.g., a conductor of the circuitry 320), or a portion of the material 325 (e.g., where a portion of the material 325 in at least the region 306 or other region is part of a distribution layer or other electrical node, which may not involve exposing a conductor of the circuitry 320).

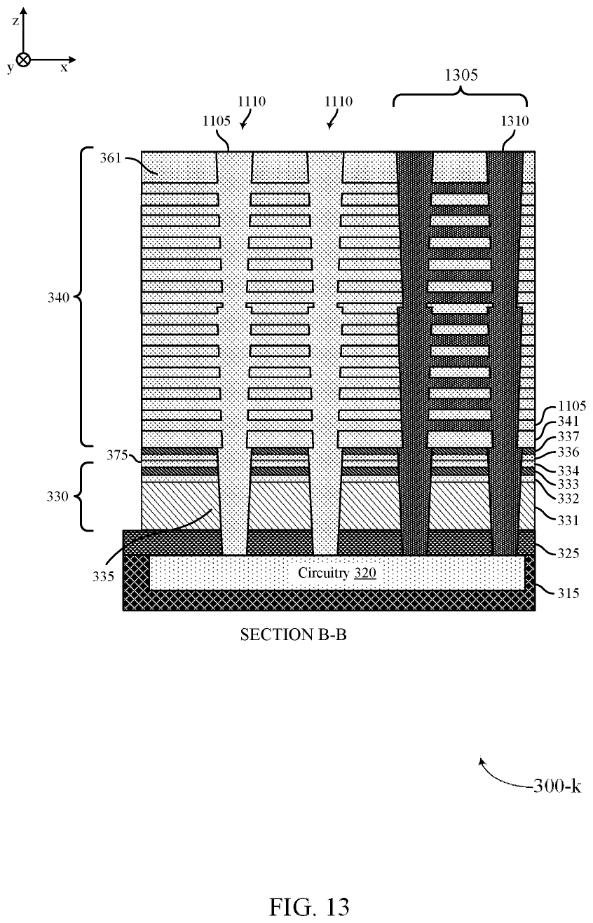

FIG. 13 illustrates the material arrangement 300 (e.g., as a material arrangement 300-k) after an eleventh set of one or more manufacturing operations as a cross-sectional side view (e.g., relative to the cut plane B-B). The eleventh set of operations may include operations (e.g., one or more deposition operations, metal fill operations) that support forming conductors 1305 at least in part by forming a material 1310 in the merged cavities 1210. For example, the third set of operations may include forming (e.g., depositing) the material 1310 in the merged cavities 1210 (e.g., through at least the stack 340 and, in some examples, through the stack 330, where applicable) and the voids 1215. The material 1310 may include one or more conductive materials, (e.g., a metal, a metal alloy, an electrically conductive ceramic such as tungsten silicide, a deposition of an electrode layer followed by a bulk fill deposition of a conductor) which may be the same as the material 325, or the material 505, or any combination thereof. The cavities 310 and the merged cavities 1210 may extend along the z-direction, such that a conductor 1305 may have extents along the z-direction. The extents along the z-direction may at least partially overlap with the extents in the z-direction associated with a pillar 307 formed in a cavity 305. Forming the material 1310 may include depositing the material 1310 within voids 1215, where applicable (e.g., in a partially-merged cavity 1210.

In some examples, such techniques may include forming the material 1310 in contact with or otherwise electrically coupled with the material 325 (e.g., where a portion of the material 325 in the region 306 or other region is part of a distribution layer or other electrical node, which may not involve forming the material 1310 in contact with a conductor of the circuitry 320). Additionally, or alternatively, such techniques may include forming the material 1310 electrically isolated from the material 325, or forming the material 1310 in contact with or otherwise electrically coupled with the circuitry 320 (e.g., in a region where the material 325 is omitted). Forming the conductor 1305 in contact with or otherwise electrically coupled with the circuitry 320 may electrically couple the conductor with one or more transistor structures (e.g., transistors formed at least in part by a doped portion of the substrate 315).

The conductors 1305 may support coupling between various features of a memory architecture 200. For example, conductors 1305 may be implemented as part of an electrical coupling between circuitry 320 and any one or more of a word line 265 (e.g., a portion of material 505), a source line 260, a select line 245, a bit line 250, or a select line 235, among other nodes of the memory architecture 200, which may support implementing the circuitry 320 for operations of the memory architecture 200. Such an electrical coupling may involve formation of one or more conductive materials, not shown, between the respective components (e.g., over or otherwise through a region 303, above or below a stack 340, where applicable, among other examples). Additionally, or alternatively, conductors 1305 may be implemented to support electrical coupling of other elements of a material arrangement 300.

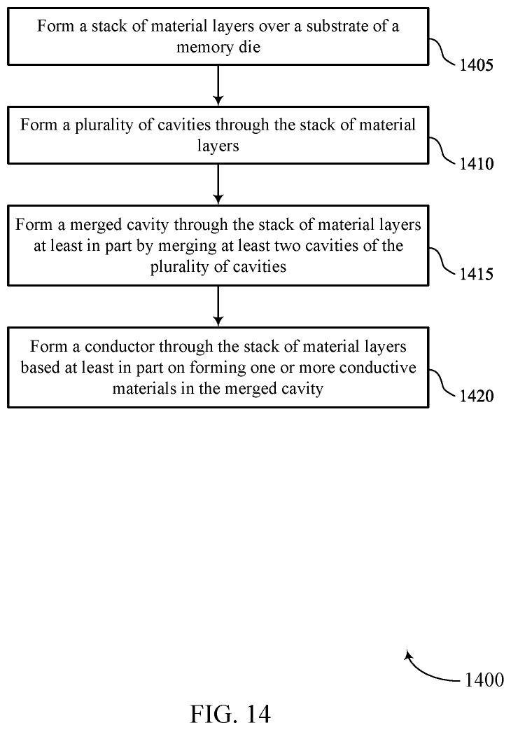

FIG. 14 illustrates a flowchart showing a method 1400 that supports merged cavities for conductor formation in a memory die in accordance with examples as disclosed herein. The operations of method 1400 may be implemented by a manufacturing system or one or more controllers associated with a manufacturing system. In some examples, one or more controllers may execute a set of instructions to control one or more functional elements of the manufacturing system to perform the desired functions. Additionally, or alternatively, the manufacturing system may perform aspects of the described functions using special-purpose hardware.

At 1405, the method may include forming a stack of material layers over a substrate of a memory die.

At 1410, the method may include forming a plurality of cavities through the stack of material layers.

At 1415, the method may include forming a merged cavity through the stack of material layers at least in part by merging at least two cavities of the plurality of cavities.

At 1420, the method may include forming a conductor through the stack of material layers based at least in part on forming one or more conductive materials in the merged cavity.

In some examples, an apparatus (e.g., a manufacturing system) as described herein may perform a method or methods, such as the method 1400. The apparatus may include features, circuitry, logic, means, or instructions (e.g., a non-transitory computer-readable medium storing instructions executable by one or more controllers to control one or more functional elements of the manufacturing system), or any combination thereof for performing the following aspects of the present disclosure:

Aspect 1: A method or apparatus including operations, features, circuitry, logic, means, or instructions, or any combination thereof for forming a stack of material layers over a substrate of a memory die; forming a plurality of cavities through the stack of material layers; forming a merged cavity through the stack of material layers at least in part by merging at least two cavities of the plurality of cavities; and forming a conductor through the stack of material layers based at least in part on forming one or more conductive materials in the merged cavity.

Aspect 2: The method or apparatus of aspect 1, further including operations, features, circuitry, logic, means, or instructions, or any combination thereof for forming a plurality of second cavities through the stack of material layers; forming a plurality of memory cells based at least in part on forming a semiconductor material in the plurality of second cavities, where the conductor is operable to electrically couple with at least a subset of the plurality of memory cells.

Aspect 3: The method or apparatus of aspect 2, where the plurality of second cavities are formed concurrently with forming the plurality of cavities.

Aspect 4: The method or apparatus of any of aspects 2 through 3, further including operations, features, circuitry, logic, means, or instructions, or any combination thereof for forming a plurality of voids based at least in part on removing respective portions of a second material of the stack of material layers from between layers of first material of the stack of material layers; forming a plurality of word lines electrically coupled with the plurality of memory cells based at least in part on forming one or more second conductive materials in the plurality of voids; and where the conductor is electrically coupled with at least one word line of the plurality of word lines.

Aspect 5: The method or apparatus of any of aspects 1 through 4, where forming the at least two cavities exposes a third conductive material between the stack of material layers and the substrate and forming the conductor includes forming a conductive material of the one or more conductive materials in contact with the third conductive material.

Aspect 6: The method or apparatus of any of aspects 1 through 5, where the conductor is electrically coupled with one or more transistors formed at least in part from a doped portion of the substrate.

Aspect 7: The method or apparatus of any of aspects 1 through 6, where merging the at least two cavities includes operations, features, circuitry, logic, means, or instructions, or any combination thereof for forming a plurality of voids between adjacent cavities of the at least two cavities based at least in part on removing respective portions of a second material of the stack of material layers between layers of a first material of the stack of material layers.

Aspect 8: The method or apparatus of any of aspects 1 through 7, where merging the at least two cavities includes operations, features, circuitry, logic, means, or instructions, or any combination thereof for removing respective portions of a first material of the stack of material layers and a second material of the stack of material layers between adjacent cavities of the at least two cavities.

Aspect 9: The method or apparatus of any of aspects 1 through 8, further including operations, features, circuitry, logic, means, or instructions, or any combination thereof for forming a dielectric material in one or more cavities of the plurality of cavities adjacent to the at least two cavities.

Aspect 10: The method or apparatus of any of aspects 1 through 9, further including operations, features, circuitry, logic, means, or instructions, or any combination thereof for forming a sacrificial material in the plurality of cavities; removing the sacrificial material from at least two second cavities of the plurality of cavities; recessing a second material of the stack of material layers via the at least two second cavities to expose sidewalls of the second material between layers of a first material of the stack of material layers; forming portions of the first material over the exposed sidewalls of the second material; removing the sacrificial material from the at least two cavities of the plurality of cavities; removing portions of second material via the at least two cavities to expose sidewalls of the portions of the first material; and forming a conductive material of the one or more conductive materials in contact with the exposed sidewalls of the portions of the first material.

Aspect 11: The method or apparatus of any of aspects 1 through 10, further including operations, features, circuitry, logic, means, or instructions, or any combination thereof for forming a sacrificial material in the plurality of cavities; removing the sacrificial material from the at least two cavities of the plurality of cavities; recessing a second material of the stack of materials via the at least two cavities to expose sidewalls of the second material between layers of a first material of the stack of material layers; forming portions of the first material over the exposed sidewalls of the second material; and forming a conductive material of the one or more conductive materials in contact with the portions of the first material.

Aspect 12: The method or apparatus of aspect 11, further including operations, features, circuitry, logic, means, or instructions, or any combination thereof for removing the sacrificial material from one or more cavities of the plurality of cavities different than the at least two cavities and forming portions of the first material in the one or more cavities.

Aspect 13: The method or apparatus of any of aspects 1 through 12, where forming the plurality of cavities includes operations, features, circuitry, logic, means, or instructions, or any combination thereof for forming a first plurality of cavities through a first subset of the stack of material layers and forming a second plurality of cavities through a second subset of the stack of material layers, each of the second plurality of cavities coincident with a respective one of the first plurality of cavities.

Aspect 14: The method or apparatus of any of aspects 1 through 13, where the stack of material layers includes alternating layers of an oxide material and a nitride material.

It should be noted that the described methods include possible implementations, and that the operations and the steps may be rearranged or otherwise modified and that other implementations are possible. Further, portions from two or more of the methods may be combined.

An apparatus is described. The following provides an overview of aspects of the apparatus as described herein:

Aspect 15: An apparatus, including: an array region over a substrate including a plurality of memory cells and a plurality of access lines coupled with the plurality of memory cells, the plurality of access lines arranged along a direction away from the substrate and each positioned between first layers of a dielectric material in the array region; and a conductor operable to couple with at least one memory cell of the plurality of memory cells, the conductor located outside the array region and including: a plurality of first conductor portions each aligned along the direction away from the substrate; and at least one second conductor portion coupled with adjacent first conductor portions of the plurality of first conductor portions, each second conductor portion located between second layers of the dielectric material outside the array region.

Aspect 16: The apparatus of aspect 15, where the conductor is operable to couple the at least one memory cell of the plurality of memory cells with one or more transistors formed at least in part from a doped portion of the substrate.

Aspect 17: The apparatus of any of aspects 15 through 16, where the conductor is in contact with a portion of at least one access line of the plurality of access lines outside the array region.

Aspect 18: The apparatus of any of aspects 15 through 17, where: the memory cells are associated with a first extent along the direction; and the conductor is associated with a second extent along the direction that at least partially overlaps the first extent.

Aspect 19: The apparatus of any of aspects 15 through 18, where subsets of memory cells of the plurality of memory cells are each arranged along a respective cell pillar extending along the direction, each cell pillar associated with a cross-sectional area that is smaller than a cross sectional area of the conductor.

Aspect 20: The apparatus of any of aspects 15 through 19, where the conductor includes a first conductive material in contact with at least a portion of the dielectric material and a second conductive material in contact with the first conductive material.

An apparatus is described. The following provides an overview of aspects of the apparatus as described herein:

Aspect 21: An apparatus, including: an array region over a substrate including a plurality of memory cells and a plurality of access lines coupled with the plurality of memory cells, the plurality of access lines arranged along a direction away from the substrate and each positioned between layers of a dielectric material in the array region; a conductor operable to couple with at least one memory cell of the plurality of memory cells, the conductor located outside the array region and associated with an axis aligned along the direction; and one or more dielectric portions around at least a portion of the conductor, each dielectric portion of the one or more dielectric portions including at least one projection of the dielectric material toward the axis.

Aspect 22: The apparatus of aspect 21, where the conductor is operable to couple the at least one memory cell of the plurality of memory cells with one or more transistors formed at least in part from a doped portion of the substrate.

Aspect 23: The apparatus of any of aspects 21 through 22, where the conductor is in contact with a portion of at least one access line of the plurality of access lines outside the array region.

Aspect 24: The apparatus of any of aspects 21 through 23, where: the memory cells are associated with a first extent along the direction; and the conductor is associated with a second extent along the direction that at least partially overlaps the first extent.

Aspect 25: The apparatus of any of aspects 21 through 24, where subsets of memory cells of the plurality of memory cells are each arranged along a respective cell pillar extending along the direction, each cell pillar associated with a cross-sectional area that is smaller than a cross sectional area of the conductor.

The terms “electronic communication,” “conductive contact,” “connected,” and “coupled” may refer to a relationship between components that supports the flow of signals between the components. Components are considered in electronic communication with (or in conductive contact with or connected with or coupled with) one another if there is any conductive path between the components that can, at any time, support the flow of signals between the components. At any given time, the conductive path between components that are in electronic communication with each other (or in conductive contact with or connected with or coupled with) may be an open circuit or a closed circuit based on the operation of the device that includes the connected components. The conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The term “coupling” (e.g., “electrically coupling”) may refer to a condition of moving from an open-circuit relationship between components in which signals are not presently capable of being communicated between the components over a conductive path to a closed-circuit relationship between components in which signals are capable of being communicated between components over the conductive path. If a component, such as a controller, couples other components together, the component initiates a change that allows signals to flow between the other components over a conductive path that previously did not permit signals to flow.

The term “isolated” refers to a relationship between components in which signals are not presently capable of flowing between the components. Components are isolated from each other if there is an open circuit between them. For example, two components separated by a switch that is positioned between the components are isolated from each other if the switch is open. If a controller isolates two components, the controller affects a change that prevents signals from flowing between the components using a conductive path that previously permitted signals to flow.

The terms “if,” “when,” “based on,” or “based at least in part on” may be used interchangeably. In some examples, if the terms “if,” “when,” “based on,” or “based at least in part on” are used to describe a conditional action, a conditional process, or connection between portions of a process, the terms may be interchangeable.

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In some other examples, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorous, boron, or arsenic. Doping may be performed during the initial formation or growth of the substrate, by ion-implantation, or by any other doping means.

A switching component or a transistor discussed herein may represent a field-effect transistor (FET) and comprise a three terminal device including a source, drain, and gate. The terminals may be connected to other electronic elements through conductive materials, e.g., metals. The source and drain may be conductive and may comprise a heavily-doped, e.g., degenerate, semiconductor region. The source and drain may be separated by a lightly-doped semiconductor region or channel. If the channel is n-type (i.e., majority carriers are electrons), then the FET may be referred to as an n-type FET. If the channel is p-type (i.e., majority carriers are holes), then the FET may be referred to as a p-type FET. The channel may be capped by an insulating gate oxide. The channel conductivity may be controlled by applying a voltage to the gate. For example, applying a positive voltage or negative voltage to an n-type FET or a p-type FET, respectively, may result in the channel becoming conductive. A transistor may be “on” or “activated” if a voltage greater than or equal to the transistor's threshold voltage is applied to the transistor gate. The transistor may be “off” or “deactivated” if a voltage less than the transistor's threshold voltage is applied to the transistor gate.

The description set forth herein, in connection with the appended drawings, describes example configurations and does not represent all the examples that may be implemented or that are within the scope of the claims. The term “exemplary” used herein means “serving as an example, instance, or illustration” and not “preferred” or “advantageous over other examples.” The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a hyphen and a second label that distinguishes among the similar components. If just the first reference label is used in the specification, the description is applicable to any one of the similar components having the same first reference label irrespective of the second reference label.

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A method, comprising:
forming a stack of material layers over a substrate of a memory die;
forming a plurality of cavities through the stack of material layers;
forming a merged cavity through the stack of material layers at least in part by merging at least two cavities of the plurality of cavities; and
forming a conductor through the stack of material layers based at least in part on forming one or more conductive materials in the merged cavity.

2. The method of claim 1, further comprising:
forming a plurality of second cavities through the stack of material layers; and
forming a plurality of memory cells based at least in part on forming a semiconductor material in the plurality of second cavities,
wherein the conductor is operable to electrically couple with at least a subset of the plurality of memory cells.

3. The method of claim 2, wherein the plurality of second cavities are formed concurrently with forming the plurality of cavities.

4. The method of claim 2, further comprising:
forming a plurality of voids based at least in part on removing respective portions of a second material of the stack of material layers from between layers of first material of the stack of material layers; and
forming a plurality of word lines electrically coupled with the plurality of memory cells based at least in part on forming one or more second conductive materials in the plurality of voids,
wherein the conductor is electrically coupled with at least one word line of the plurality of word lines.

5. The method of claim 1, wherein:
forming the at least two cavities exposes a third conductive material between the stack of material layers and the substrate; and
forming the conductor comprises forming a conductive material of the one or more conductive materials in contact with the third conductive material.

6. The method of claim 1, wherein the conductor is electrically coupled with one or more transistors formed at least in part from a doped portion of the substrate.

7. The method of claim 1, wherein merging the at least two cavities comprises:
forming a plurality of voids between adjacent cavities of the at least two cavities based at least in part on removing respective portions of a second material of the stack of material layers between layers of a first material of the stack of material layers.

8. The method of claim 1, wherein merging the at least two cavities comprises:
removing respective portions of a first material of the stack of material layers and a second material of the stack of material layers between adjacent cavities of the at least two cavities.

9. The method of claim 1, further comprising:
forming a sacrificial material in the plurality of cavities;
removing the sacrificial material from at least two second cavities of the plurality of cavities;
recessing a second material of the stack of material layers via the at least two second cavities to expose sidewalls of the second material between layers of a first material of the stack of material layers;
forming portions of the first material over the exposed sidewalls of the second material;
removing the sacrificial material from the at least two cavities of the plurality of cavities;
removing portions of second material via the at least two cavities to expose sidewalls of the portions of the first material; and
forming a conductive material of the one or more conductive materials in contact with the exposed sidewalls of the portions of the first material.

10. The method of claim 1, further comprising:
forming a sacrificial material in the plurality of cavities;
removing the sacrificial material from the at least two cavities of the plurality of cavities;
recessing a second material of the stack of materials via the at least two cavities to expose sidewalls of the second material between layers of a first material of the stack of material layers;
forming portions of the first material over the exposed sidewalls of the second material; and
forming a conductive material of the one or more conductive materials in contact with the portions of the first material.

11. The method of claim 1, wherein the stack of material layers comprises alternating layers of an oxide material and a nitride material.

12. An apparatus, comprising:
an array region over a substrate comprising a plurality of memory cells and a plurality of access lines coupled with the plurality of memory cells, the plurality of access lines arranged along a direction away from the substrate and each positioned between first layers of a dielectric material in the array region;
a conductor operable to couple with at least one memory cell of the plurality of memory cells, the conductor located outside the array region and comprising:
a plurality of first conductor portions each aligned along the direction away from the substrate; and
at least one second conductor portion coupled with adjacent first conductor portions of the plurality of first conductor portions, each second conductor portion located between second layers of the dielectric material outside the array region.

13. The apparatus of claim 12, wherein the conductor is operable to couple the at least one memory cell of the plurality of memory cells with one or more transistors formed at least in part from a doped portion of the substrate.

14. The apparatus of claim 12, wherein the conductor is in contact with a portion of at least one access line of the plurality of access lines outside the array region.

15. The apparatus of claim 12, wherein:
the plurality of memory cells are associated with a first extent along the direction; and
the conductor is associated with a second extent along the direction that at least partially overlaps the first extent.

16. The apparatus of claim 12, wherein subsets of memory cells of the plurality of memory cells are each arranged along a respective cell pillar extending along the direction, each cell pillar associated with a cross-sectional area that is smaller than a cross sectional area of the conductor.

17. An apparatus, comprising:
an array region over a substrate comprising a plurality of memory cells and a plurality of access lines coupled with the plurality of memory cells, the plurality of access lines arranged along a direction away from the substrate and each positioned between layers of a dielectric material in the array region;
a conductor operable to couple with at least one memory cell of the plurality of memory cells, the conductor located outside the array region and associated with an axis aligned along the direction; and
one or more dielectric portions around at least a portion of the conductor, each dielectric portion of the one or more dielectric portions comprising at least one projection of the dielectric material toward the axis.

18. The apparatus of claim 17, wherein the conductor is operable to couple the at least one memory cell of the plurality of memory cells with one or more transistors formed at least in part from a doped portion of the substrate.

19. The apparatus of claim 17, wherein the conductor is in contact with a portion of at least one access line of the plurality of access lines outside the array region.

20. The apparatus of claim 17, wherein subsets of memory cells of the plurality of memory cells are each arranged along a respective cell pillar extending along the direction, each cell pillar associated with a cross-sectional area that is smaller than a cross sectional area of the conductor.
